(19) United States
(12) Patent Application Publication
(10) Pub. No.: US 2025/0105040 A1
(43) Pub. Date: Mar. 27, 2025

(54) SUBSTRATE TRANSFER APPARATUS AND SUBSTRATE PROCESSING APPARATUS

(71) Applicant: SCREEN Holdings Co., Ltd., Kyoto (JP)

(72) Inventor: Yuichi TAKAYAMA, Kyoto (JP)

(21) Appl. No.: 18/892,288

(22) Filed: Sep. 20, 2024

(30) Foreign Application Priority Data
Sep. 21, 2023 (JP) 2023-155674

(51) Int. Cl. H01L 21/67; B65G 1/04; H01L 21/673; H01L 21/687

(52) U.S. Cl. CPC H01L 21/67259; B65G 1/04; H01L 21/68707; B65G 2201/0297; B65G 2203/042; H01L 21/6732

(57) ABSTRACT

A substrate transfer apparatus including the control unit is configured to advance the sensor holding member between a first substrate that is a substrate to be transferred and a second substrate that is on a lower side of the first substrate, and to measure a minimum distance between the substrates, based on a sum of a first minimum distance and a second minimum distance, the first minimum distance being a distance with respect to the substrate at a first measurement point where the first sensor is closest to the first substrate, and the second minimum distance being a distance with respect to the substrate at a second measurement point where the second sensor is closest to the second substrate, and to adjust a height at which the hand is advanced, based on the minimum distance between the substrates so that a distance between the hand and the first substrate and a distance between the hand and the second substrate both become equal to or more than a predetermined distance, when the hand is advanced between the first substrate and the second substrate.

This application claims priority to Japanese Patent Application No. 2023-155674 filed on Sep. 21, 2023, the subject matter of which is incorporated herein by reference in entirety.

### BACKGROUND OF THE INVENTION

### Field of the Invention

The present invention relates to a substrate transfer apparatus and a substrate processing apparatus for transferring various types of substrates such as a semiconductor substrate, a substrate for a flat panel display (FPD) including a liquid crystal display and an organic electroluminescence (EL) display device, a glass substrate for a photomask, and a substrate for an optical disk.

### Description of the Related Art

The substrate processing apparatus described in JP 2016-72384 A includes a placing table and a substrate transfer apparatus. A carrier capable of storing substrates in a stack, with a space therebetween, is placed on the placing table, and the substrate transfer apparatus transfers the substrates from the carrier. The substrate processing apparatus disclosed in JP 2016-72384 A includes a mapping sensor that examines how the stack of substrates are organized in the carrier. The mapping sensor generates mapping data to be referred to when the substrates are transferred from the carrier.

### LIST OF DOCUMENTS

JP 2016-72384 A

Such a conventional substrate transfer apparatus is only capable of recognizing the substrate distribution in the carrier, that is, which parts of the carrier are loaded with the substrates, and not capable of recognizing the shapes of the substrates, specifically, the widths of the substrates or variation in the size of the space between two adjacent upper and lower substrates, the variation being resultant of thicknesses or warpage of the substrates. If the substrate is not transferred considering such shape of the substrate, inconvenience may occur. For example, a hand for transferring the substrate may come into contact with the substrate.

### SUMMARY OF THE INVENTION

The present invention has been made in view of such a situation, and an object of the present invention is to provide a substrate transfer apparatus that recognizes the shape of a substrate, and prevents any inconvenience caused by the shape of the substrate.

In order to address the disadvantage described above, the present invention has the following configuration.

In other words, the present invention is a substrate transfer apparatus including:
a hand configured to hold and to transfer one substrate at a time, from a carrier that stores a plurality of substrates, in horizontal postures, with a predetermined interval between the substrates in a vertical direction, and that has an opening for taking out and storing substrate on one side surface, by advancing between adjacent upper and lower substrates;
a sensor holding member that is a member configured to be advanced between the adjacent upper and lower substrates, and that includes a first sensor configured to measure a distance with respect to upper one of the adjacent upper and lower substrates, and a second sensor configured to measure a distance with respect to a lower one of the adjacent upper and lower substrates; and
a control unit configured to control to advance and to retract the hand and the sensor holding member between the adjacent upper and lower substrates, through the opening of the carrier, wherein
the control unit is configured:
to advance the sensor holding member between a first substrate that is a substrate to be transferred and a second substrate that is on a lower side of the first substrate, and to measure a minimum distance between the substrates, based on a sum of a first minimum distance and a second minimum distance, the first minimum distance being a distance with respect to the substrate at a first measurement point where the first sensor is closest to the first substrate, and the second minimum distance being a distance with respect to the substrate at a second measurement point where the second sensor is closest to the second substrate, and
to adjust a height at which the hand is advanced, based on the minimum distance between the substrates so that a distance between the hand and the first substrate and a distance between the hand and the second substrate both become equal to or more than a predetermined distance, when the hand is advanced between the first substrate and the second substrate.

[Operation and Effect] The substrate transfer apparatus described above includes the sensor holding member including the first sensor and the second sensor, separately from the hand for transferring a substrate. According to the present invention, when the first substrate in the carrier is to be transferred, the sensor holding member is at first inserted between the first substrate and the second substrate. The sensor holding member then measures the distance between the first substrate and the second substrate. Because the positions where substrates are placed in the carrier are fixed, the distance between the first substrate and the second substrate should remain constant. However, the first substrate and the second substrate are actually not always flat. Therefore, in the actual measurement of the distance between the first substrate and the second substrate, the minimum distance between the substrates may be longer or shorter than expected. At the same time, the position of the midpoint between the substrates may be higher or lower than expected.

According to the present invention, when the hand advances between the first substrate and the second substrate, the height at which the hand is advanced is adjusted in such a manner that a predetermined clearance or more is ensured both between the hand and the first substrate and between the hand and the second substrate. With this configuration, it is possible to prevent the hand from coming into contact with any portion of the first substrate other than its peripheral portion by coming too close to the first substrate. In the same manner, it is possible to prevent the hand from coming into contact with any portion of the second substrate other than its peripheral portion, by coming too close to the second substrate.

In the substrate transfer apparatus described above, preferably,
the hand has a tip end provided with a guide member against which an end of a substrate comes into abutment,
the first sensor and the second sensor are provided to a tip end of the sensor holding member, and
the tip end of the sensor holding member has a thickness, in a height direction, thinner than a thickness of the tip end of the hand in the height direction.

[Operation and Effect] In the configuration described above, the thickness of the tip end of the sensor holding member including the first sensor and the second sensor at is less than the thickness of the tip end of the hand including the guide member. With this configuration, the sensor holding member can be advanced between the substrates between which the hand cannot, so that the minimum distance between the substrates can be measured, reliably.

In the substrate transfer apparatus described above, preferably,
the first sensor measures a distance while being moved from an end of the first substrate, the end being positioned at the opening of the carrier, toward a back of the carrier,
the second sensor measures a distance while being moved from an end of the second substrate, the end being positioned at the opening of the carrier, toward the back of the carrier, and
the control unit is configured to adjust a height at which the hand is advanced in such a manner that a predetermined distance or more is ensured between the hand and the first substrate and between the hand and the second substrate, at the first measurement point where the first sensor is positioned closest to the first substrate and at the second measurement point at which the second sensor is positioned closest to the second substrate.

[Operation and Effect] In the configuration described above, the height at which the hand is advanced is adjusted in such a manner that a predetermined clearance or more is ensured both between the hand and the first substrate and between the hand and the second substrate, at the position where the first substrate and the second substrate are closest to each other. With this configuration, the hand is prevented from coming into contact with the substrate at the position where the first substrate and the second substrate are closest to each other.

In the substrate transfer apparatus described above, preferably,
the control unit is configured to adjust the height at which the hand is advanced in such a manner that a distance between the hand and the first substrate at the first measurement point becomes equal to a distance between the hand and the second substrate at the second measurement point.

[Operation and Effect] In the configuration described above, the height at which the hand is advanced is adjusted in such a manner that the clearance between the hand and the first substrate is equal to the clearance between the hand and the second substrate. With this configuration, it is possible to ensure a sufficient distance not only between the hand and the first substrate but also between the hand and the second substrate, during the transfer of the substrate. Therefore the hand is enabled to transfer the substrate more reliably.

In the substrate transfer apparatus described above, preferably,
the sensor holding member is configured not to transfer the substrate.

[Operation and Effect] In the configuration described above, the sensor holding member is configured not to transfer the substrate. With this configuration, it is not necessary to provide the sensor holding member with the guide member for holding the substrate, and to advance the sensor holding member between the substrates more smoothly.

In the substrate transfer apparatus described above, preferably,
when a distance between the first substrate and the second substrate is too short to ensure the predetermined distance or more between the hand and the first substrate at the first measurement point and between the hand and the second substrate at the second measurement point simultaneously, the hand is not advanced between the first substrate and the second substrate.

[Operation and Effect] In the configuration described above, when the distance between the first substrate and the second substrate is too short to ensure a predetermined clearance or more between the hand and the first substrate and between the hand and the second substrate at the same time, it is determined that the hand is not capable of transferring the first substrate, and the hand is not advanced between the first substrate and the second substrate. With this configuration, it is possible to prevent the hand from coming into contact with any portion of the substrate other than its peripheral portion, more reliably.

In the substrate transfer apparatus described above, preferably,
a top surface of the sensor holding member is positioned higher than a bottom end of the first sensor, and
a bottom surface of the sensor holding member is positioned lower than a top end of the second sensor.

[Operation and Effect] In the configuration described above, it is possible to reduce the amount by which the first sensor and the second sensor protrude, by the amount corresponding to the thickness of the sensor holding member. In this manner, because the height of the sensor holding member can be reduced as much as possible, it is possible to suppress the chances of the sensor holding member not being capable of being advanced between the substrates.

In the substrate transfer apparatus described above,
the hand has a first holding body that holds one end of the substrate, and a second holding body that holds another end of the substrate,
the sensor holding member includes at least two sensor groups each including the first sensor and the second sensor,
the first sensor group measures a distance between the first substrate and the second substrate at a position where the first holding body is advanced, and
a second sensor group measures a distance between the first substrate and the second substrate at a position where the second holding body is advanced.

[Operation and Effect] In the configuration described above, the sensor holding member includes the first sensor group that measures the minimum distance between the substrates at the position of the first holding body of the hand, and the sensor holding member includes the second sensor group that measures the minimum distance between the substrates at the position of the second holding body of the hand. In this manner, it is possible to prevent the hand from coming into contact with any portion of the substrate other than its peripheral portion, more reliably.

In the substrate transfer apparatus described above, the sensor holding member includes a first projection extending correspondingly to the first holding body, and a second projection extending correspondingly to the second holding body.

[Operation and Effect] In the configuration described above, the sensor holding member includes the first projection extending in a first direction corresponding to the first holding body, and the second projection extending in the first direction corresponding to the second holding body. By providing the sensor holding member with a shape similar to the shape of the hand, it is possible to collect the distance-related information required for the transfer, more reliably.

In the substrate transfer apparatus described above, preferably, the sensor holding member includes the sensor group at a tip end of the first projection, and include the sensor group at a tip end of the second projection.

[Operation and Effect] In the configuration described above, the sensor group is provided at the tip of the first projection of the sensor holding member, and the sensor group is provided to the tip of the second projection of the sensor holding member. With this configuration, it is possible to measure the minimum distance between the substrates near the back of the carrier, by moving the sensor holding member slightly.

In the substrate transfer apparatus described above, preferably,
the sensor holding member
is provided with the first sensor and the second sensor at the same position of the first projection, and
is provided with the first sensor and the second sensor at the same position of the second projection.

[Operation and Effect] In the configuration described above, the sensor holding member is provided with the first sensor and the second sensor at the same position of the first projection in the first direction. The sensor holding member is also provided with the first sensor and the second sensor at the same position in the second projection. With this configuration, because it is possible to make measurements with respect to the substrate on the upper side of the sensor holding member (first substrate) and the substrate on the lower side of the sensor holding member (second substrate) under the same condition, the minimum distance between the substrates can be calculated more accurately.

In the substrate transfer apparatus described above, preferably,
the control unit does not advance the hand between the first substrate and the second substrate when the distance between the first substrate and the second substrate is too short to advance the sensor holding member between the first substrate and the second substrate.

[Operation and Effect] In the configuration described above, when the distance between the first substrate and the second substrate is too short to advance the sensor holding member into the space between the first substrate and the second substrate, it is determined that the hand cannot transfer the first substrate, and the hand is not advanced between the first substrate and the second substrate. With this configuration, it is possible to prevent the hand from coming into contact with any portion of the substrate other than its peripheral portion, more reliably.

In the substrate transfer apparatus described above, preferably
when the first substrate is left out in the carrier, after the second substrate is transferred from the carrier, the control unit causes the hand to transfer the first substrate.

[Operation and Effect] In the configuration described above, when the first substrate having been previously determined as not transferable is still in the carrier after the second substrate is transferred from the carrier, the hand is caused to transfer the first substrate. With this configuration, it is possible to avoid the first substrate from being left out in the carrier until the end of the process.

In the substrate transfer apparatus described above, preferably, the control unit is configured:
to advance the sensor holding member between the first substrate and the second substrate at a first speed, and
to advance the hand between the first substrate and the second substrate at a second speed that is higher than the first speed.

[Operation and Effect] In the configuration described above, because the sensor holding member is advanced between the substrates at a speed faster than that of the hand, it is possible to achieve an effect of speeding up the substrate transfer processing.

In the substrate transfer apparatus described above, preferably,
the sensor holding member is at the same position as the position of the hand before being advanced between the substrates.

[Operation and Effect] In the configuration described above, the sensor holding member is at the same position as the position of the hand before being advanced between the substrates. With this configuration, it is possible to implement the present invention by causing a single robot to use the hand and the sensor holding member, selectively.

In the substrate transfer apparatus described above, preferably,
the hand is also used as the sensor holding member, and the first sensor and the second sensor are mounted on the hand.

[Operation and Effect] In the configuration described above, the sensor group is provided at the tip end of the hand body, not on the guide member. With this configuration, it is possible to provide the substrate transfer apparatus having a simple structure, without the sensor holding member.

In addition to the aspects described above, the following aspects are disclosed herein.

In other words, the present invention provides a substrate transfer apparatus including:
a first hand, for a high-speed transfer, that transfers one substrate at a time from a carrier that stores a plurality of substrates in horizontal postures with a predetermined interval between the substrates in a vertical direction;
a second hand, for a low-speed transfer, that transfers one substrate at a time from a carrier that stores a plurality of substrates in horizontal postures with the predetermined interval between the substrates in the vertical direction; and
a control unit that control to advance and to retract the first hand or the second hand with respect to the substrate in a first direction.

[Operation and Effect] The substrate transfer apparatus described above includes the control unit having two types of hands that are the first hand for a high-speed transfer, and the second hand for a low-speed transfer, and transfers the substrate by using the first hand and the second hand selectively. With such a configuration, it is possible to use the first hand to make a high-speed transfer when the shape of the substrate is closer to flat, and to use the second hand to make a low-speed transfer when the shape of the substrates is more warped. In other words, with the substrate transfer apparatus according to the present invention, it is possible to transfer the substrates using a method more suitable for the actual conditions of the substrates stored in the carrier.

In the substrate transfer apparatus described above,
the first hand has a tip end provided with a first guide member that comes into contact with an end of a substrate;
the second hand has a tip end provided with a second guide member that comes into contact with an end of a substrate; and
the tip end of the second hand has a thickness thinner in a height direction than a thickness of the tip end of the first hand in the height direction.

[Operation and Effect] With the configuration described above, the tip end of the second hand has a thickness thinner in the height direction than the tip end of the first hand in the height direction. With this configuration, even when the substrates are warped extensively, and the distance between the substrates is short, it is possible to transfer the substrate to be transferred more reliably, by using the second hand.

In the substrate transfer apparatus described above,
the first hand includes a first holding body that extends in a first direction and holds one end of the substrate, and a second holding body that extends in the first direction and holds the other end of the substrate,
the second hand includes a first blade that extends in the first direction and holds one end of a substrate, and a second blade that extends in the first direction and holds the other end of the substrate, and
a space between the first holding body and the second holding body is smaller than a space between the first blade and the second blade.

[Operation and Effect] With the configuration described above, the space between the first holding body and the second holding body in the first hand is smaller than the space between the first blade and the second blade in the second hand. With such a configuration, because the first hand can hold the substrate more reliably, it is possible to transfer the substrate at a high speed. By contrast, the second hand can hold a warped substrate, reliably, between the first blade and the second blade.

In the substrate transfer apparatus described above,
the first hand includes a pusher that grips a substrate, and
the second hand does not include the pusher.

[Operation and Effect] With the configuration described above, the first hand includes the pusher that grips the substrate. With this, the first hand can hold the substrate reliably, and transfer the substrate at a high speed. The second hand does not have a pusher. With this configuration, it is possible to simplify the structure of the apparatus, and to reduce the thickness of the second hand in the height direction.

In the substrate transfer apparatus according to the present invention, there is no disadvantage caused by the shape of the substrate.

### BRIEF OF DESCRIPTION OF THE DRAWINGS

FIG. 1 is a plan view for explaining the entire configuration of a substrate processing apparatus according to Embodiment 1;

FIG. 2 is a front view for explaining a configuration of a carrier according to Embodiment 1;

FIG. 3 is a schematic diagram for explaining a configuration of an indexer robot according to Embodiment 1;

FIG. 4A is a schematic diagram for explaining a sensor holding member and a hand according to Embodiment 1;

FIG. 4B is a schematic diagram for explaining the sensor holding member and the hand according to Embodiment 1;

FIG. 5 is a plan view for explaining a pickup hand and a return hand according to Embodiment 1;

FIG. 6 is a plan view for explaining the sensor holding member according to Embodiment 1;

FIG. 7A is a schematic diagram for explaining an operation of an indexer robot according to Embodiment 1;

FIG. 7B is a schematic diagram for explaining an operation of the indexer robot according to Embodiment 1;

FIG. 7C is a schematic diagram for explaining the operation of the indexer robot according to Embodiment 1;

FIG. 8A is a schematic diagram for explaining the operation of the indexer robot according to Embodiment 1;

FIG. 8B is a schematic diagram for explaining the operation of the indexer robot according to Embodiment 1;

FIG. 8C is a schematic diagram for explaining the operation of the indexer robot according to Embodiment 1;

FIG. 9A is a schematic diagram for explaining the operation of the indexer robot according to Embodiment 1;

FIG. 9B is a schematic diagram for explaining the operation of the indexer robot according to Embodiment 1;

FIG. 10A is a schematic diagram for explaining the operation of the indexer robot according to Embodiment 1;

FIG. 10B is a schematic diagram for explaining the operation of the indexer robot according to Embodiment 1;

FIG. 10C is a schematic diagram for explaining the operation of the indexer robot according to Embodiment 1;

FIG. 11A is a schematic diagram for explaining the operation of the indexer robot according to Embodiment 1;

FIG. 11B is a schematic diagram for explaining the operation of the indexer robot according to Embodiment 1;

FIG. 12 is a flowchart for explaining an operation of a substrate processing apparatus according to Embodiment 1;

FIG. 13 is a plan view for explaining the operation of the substrate processing apparatus according to Embodiment 1;

FIG. 14 is a schematic diagram for explaining a configuration of an indexer robot according to Embodiment 2;

FIG. 15A is a schematic diagram for explaining a sensor holding member and a hand according to Embodiment 2;

FIG. 15B is a schematic diagram for explaining the sensor holding member and the hand according to Embodiment 2;

FIG. 16 is a plan view for explaining a first pickup hand and a first return hand according to Embodiment 2;

FIG. 17 is a plan view for explaining a second pickup hand and a second return hand according to Embodiment 2;

FIG. 18 is a flowchart for explaining an operation of a substrate processing apparatus according to Embodiment 2;

FIG. 19 is a schematic diagram for explaining the configuration according to the one modification of the present invention.

FIG. 20 is a schematic diagram for explaining a configuration according to the one modification of the present invention;

FIG. 21 is a schematic diagram for explaining a configuration according to one modification of the present invention; and

FIG. 22 is a schematic diagram for explaining a configuration according to one modification of the present invention.

### DESCRIPTION OF THE PREFERRED EMBODIMENTS

Some embodiments of the present invention will now be described with reference to drawings. Each of the following embodiments is a substrate processing apparatus including a substrate transfer apparatus according to the present invention. The substrate transfer apparatus according to the present invention corresponds to an indexer block included in a substrate processing apparatus according to the embodiment. An indexer block includes an indexer robot having a hand for transferring a substrate, and a sensor holding member for measuring the distance between substrate.

### Embodiment 1

### 1. Overall Configuration

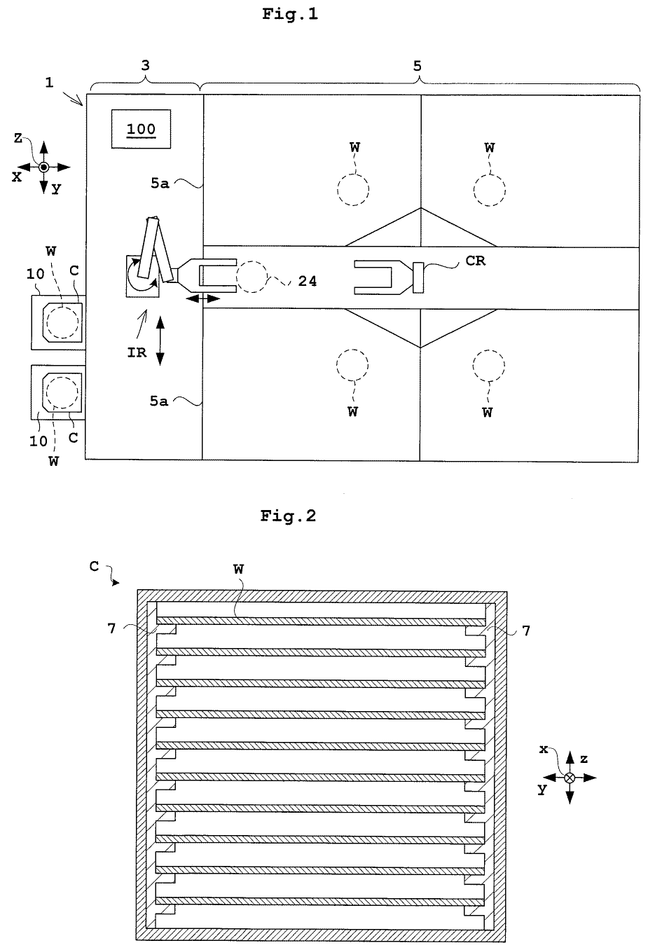

As illustrated in FIG. 1, a substrate processing apparatus 1 according to this example includes a load port 10, an indexer block 3, and a processing block 5. The substrate processing apparatus 1 according to this example is related to single-wafer processing, and is configured to pick up substrates W in horizontal postures one by one from a carrier C, perform substrate processing, and return the substrates W one by one into the carrier.

In the explanation herein, for the convenience of description, the direction along which the indexer block 3 and the processing block 5 are disposed in the substrate processing apparatus 1 will be referred to as a “front-back direction X”. The front-back direction X extends horizontally. In the front-back direction X, the direction from the processing block 5 toward the indexer block 3 in the substrate processing apparatus 1 will be referred to as “frontward”. The direction opposite to the frontward direction will be referred to as “rearward”. The direction extending horizontally and orthogonally to the front-back direction X will be referred to as “width direction Y”. One of the “width direction Y” will be referred to as “rightward” for the convenience of description, and the other will be referred to as “leftward” for the convenience of description. The direction orthogonal to the front-back direction X as well as to the width direction Y (height direction) will be referred to as a “vertical direction Z” for the convenience of description. In each of the drawings, the front side, the rear side, the right side, the left side, the upper side, and the lower side are indicated as appropriate, for reference.

The load port 10 is a carrier placement shelf for placing a carrier C. The plurality of load ports 10 are disposed along the width direction Y, and each of the plurality of load ports 10 is available for the placement of one carrier C.

The carrier C stores therein a plurality of substrates W in horizontal postures, with a predetermined interval therebetween in the vertical direction Z. The carrier C also has an opening for taking out and for storing a substrate, on one side surface. Within one carrier C, a plurality of (e.g., twenty five) substrates W in horizontal postures are stacked and stored at constant intervals. FIG. 2 is a cross-sectional view for explaining a configuration of the carrier C. In the carrier C, each end of the carrier housing has a comb-like member 7 having a plurality of protrusions for placing the substrate W. The protrusions of the comb-like member 7 are structures on which the ends of the substrate W are placed. The protrusions extends in the front-back direction X. The protrusions are provided at intervals of 1 cm. One example of the carrier C is a sealed front opening unified pod (FOUP). In the present invention, it is also possible to use an open container as the carrier C.

The indexer block 3 corresponds to a substrate transfer apparatus according to the present invention. The indexer block 3 has a rectangular shape that is elongated in the width direction Y. The indexer block 3 includes the indexer robot IR. The indexer robot IR is horizontally movable in the width direction Y. The indexer robot IR has a hand capable of holding and transferring the substrate W. The hand is an articulated arm configured to be capable of making a turn, moving up and down, and moving back and forth. The indexer robot IR can access the carrier C on the load port 10, and a path 24 provided in front of the processing block 5. The indexer robot IR can perform two operations one of which is an operation of picking up the substrates W in the horizontal posture one by one from the carrier C and placing the substrate W on the path 24, and the other of which is an operation of picking up the substrates W in the horizontal posture one by one from the path 24, and returning the substrate W into the carrier C. The indexer robot IR transfers an unprocessed substrate W held in the carrier C onto the path 24. A processed substrate W is placed on the path 24, and is returned, by the indexer robot IR, to the carrier C.

The processing block 5 corresponds to a processing unit according to the present invention. The processing block 5 is configured to perform predetermined processing on the substrate W. The processing block 5 includes an arrangement of a plurality of single-wafer processing chambers 5a. In other words, three single-wafer processing chambers 5a are installed in each of a middle layer region, an upper layer region, and a lower layer region, to form a stack. Two stacks are disposed in the front side and the rear side, respectively, on the right side of the processing block 5. In the same manner, two stacks are disposed on the front side and the rear side, respectively, on the left side of the processing block 5. Therefore, twelve single-wafer processing chambers 5a in total are installed in the processing block 5. Along the center of the processing block 5, a substrate transfer section extending in the front-back direction X is provided. A center robot CR is enabled to move back and forth along the substrate transfer section, and to pick up one substrate W, in the horizontal posture, at a time from the path 24, and transfer the substrate W into one of the single-wafer processing chambers 5a. The center robot CR is also enabled to pick up one substrate W, in the horizontal posture, at a time from the single-wafer processing chamber 5a, and to return the substrate W to the path 24. In the manner described above, the center robot CR is enabled to access each of the single-wafer processing chambers 5a and the path 24.

An example of the substrate processing performed in the single-wafer processing chamber 5a includes substrate cleaning processing. The substrate processing apparatus 1 according to this example may be configured to perform various types of substrate processing that uses a chemical liquid, in addition to the substrate cleaning processing.

### 2. Configuration of Indexer Robot

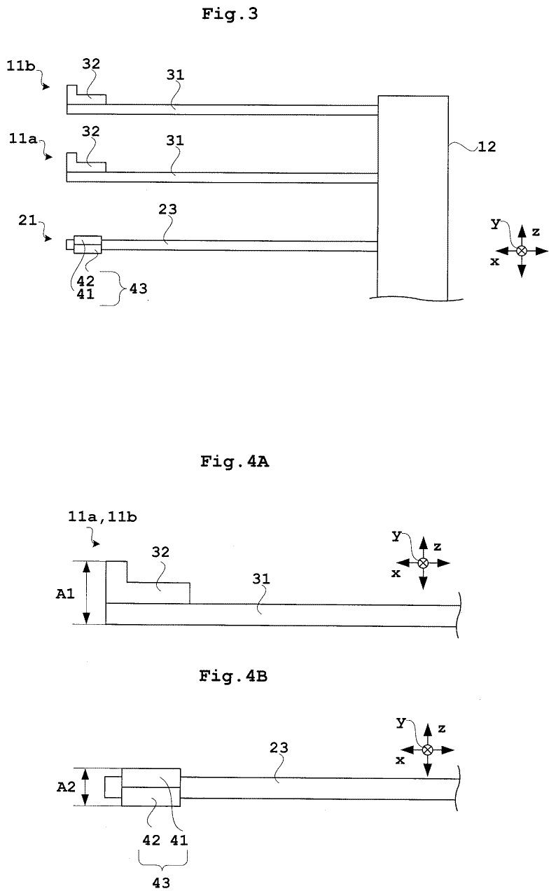

FIG. 3 schematically illustrates tip ends involved in holding of a substrate, in the indexer robot TR. The indexer robot IR includes a pickup hand 11a, a return hand 11b, and a sensor holding member 21. The return hand 11b, the pickup hand 11a, and the sensor holding member 21 are disposed on top of each other in the vertical direction Z, and held by an arm 12. The arm 12 can advance and retreat the return hand 11b, the pickup hand 11a, and the sensor holding member 21 independently, in the front-back direction X. The sensor holding member 21 is set to the same position as the pickup hand 11a and the return hand 11b in the front-back direction X, before being advanced into the space between the substrates W. In the configuration illustrated in FIG. 3, the return hand 11b, the pickup hand 11a, and the sensor holding member 21 are arranged from the top to the bottom, in the order listed herein, but the order in which these members are arranged may be changed as appropriate.

The pickup hand 11a corresponds to a hand according to the present invention. The pickup hand 11a holds one unprocessed substrate W at a time from the carrier C by advancing between adjacent upper and lower substrates W, and transfers the substrate W onto the path 24. The pickup hand 11a includes a hand body 31 and a guide member 32. The hand body 31 has a flat shape so as to be able to advance into the space between the substrates. The guide member 32 is positioned at the tip end of the pickup hand 11a, and is configured to abut against the end of the substrate W. In other words, the guide member 32 is a tab provided at the tip end of the hand body 31, and is a member that comes into contact with the substrate W. The guide member 32 is provided on the top surface of the hand body 31. The guide member 32 is thus configured to hold the upper substrate W from the bottom. The guide member 32 has a thick portion and a thin portion. The guide member 32 thus has parts with different thicknesses in the height direction. A wall provided to the thick portion of the guide member 32, the wall facing the base end of the pickup hand 11a, can come into contact with the peripheral end (bevel portion) of the substrate W. A flat part of the thin portion of the guide member 32, the flat part facing upwards, can come into contact with the peripheral portion of the bottom surface of the substrate. A guide member is also provided at the base end of the hand body 31 (not illustrated in FIG. 3). These guide members form a contact portion that comes into contact with the substrate W, in the pickup hand 11a.

The return hand 11b has the same configuration as the pickup hand 11a described above. In other words, the return hand 11b includes the hand body 31 and the guide member 32. The return hand 11b and the pickup hand 11a share the same configuration in which the guide members 32 are provided at the tip end and the base end of the hand body 31, respectively, and each of the guide member 32 has a thick portion and a thin portion. The return hand 11b according to this example is provided to transfer cleaned substrates W. By using different hands in a path for moving forwards and a path for moving rearwards in the operation of moving the substrate W back and forth, it is not necessary to use a hand having held an uncleaned substrate W in holding a cleaned substrate W. Therefore, by providing the return hand 11b, the cleanliness of the cleaned substrate W can be maintained.

The sensor holding member 21 in FIG. 3 is a member that is advanced between the adjacent upper and lower substrates W. The sensor holding member 21 holds a first sensor 41 that measures the distance with respect to the substrate W on the upper side, and a second sensor 42 that measures the distance with respect to the substrate W on the lower side. The sensor holding member 21 includes a sensor group 43 including the first sensor 41 and the second sensor 42. The sensor holding member 21 has a flat shape so as to be able to advance into the space between the substrates. The first sensor 41 and the second sensor 42 are provided at the tip end of the sensor holding member 21. The sensor holding member 21 is not configured to transfer the substrate W. The sensor holding member 21, the first sensor 41, and the second sensor 42 do not come into contact with the substrate W. The holding member body 23 is a member that supports the first sensor 41 and the second sensor 42. The length by which the first sensor 41 protrudes with respect to the holding member body 23 is equal to the length by which the second sensor 42 protrudes with respect to the holding member body 23.

The second sensor 42 is provided under the first sensor 41. The first sensor 41 and the second sensor 42 are thus stacked in the vertical direction Z, to form the sensor group 43. The top surface of the sensor holding member 21 is positioned higher than the bottom end of the first sensor 41. In other words, a part of the first sensor 41 is embedded in the sensor holding member 21. In the same manner, the bottom surface of the sensor holding member 21 is positioned lower than the top end of the second sensor 42. In other words, a part of the second sensor 42 is embedded in the sensor holding member 21. The sensor holding member 21 has a through hole for fitting the sensor group 43, and the sensor group 43 is held by the sensor holding member 21 via the through hole. With this configuration, it is possible to minimize the amounts by which the first sensor 41 and the second sensor 42 protrude with respect to the sensor holding member 21.

Specifically, ultrasonic distance sensors (ranging sensors) may be used as the first sensor 41 and the second sensor 42. The first sensor 41 emits an ultrasonic wave upwards with respect to the sensor holding member 21, and the second sensor 42 emits an ultrasonic wave downwards with respect to the sensor holding member 21. The first sensor 41 measures the distance between the sensor holding member 21 and the upper substrate W by receiving the ultrasonic wave reflected from the upper substrate W and returning to the first sensor 41. The second sensor 42 measures the distance between the sensor holding member 21 and the lower substrate W by receiving the ultrasonic wave reflected from the lower substrate W and returning to the second sensor 42. In this manner, it is possible to measure the distance with respect to the substrate W on the upper side of the sensor holding member 21 and the distance with respect to the substrate W on the lower side the sensor holding member 21, on the basis of the outputs of the first sensor 41 and the second sensor 42, respectively.

FIG. 4A illustrates the tip end of the pickup hand 11a and the return hand 11b, and FIG. 4B illustrates the tip end of the sensor holding member 21. A thickness A1 of the tip end of the pickup hand 11a and the return hand 11b in the vertical direction Z corresponds to the distance between the top end of the thick portion of the guide member 32 and the bottom end of the hand body 31. A thickness A2 of the tip of the sensor holding member 21 in the vertical direction Z corresponds to a distance between the top end of the first sensor 41 and the bottom end of the second sensor 42. The thickness of the tip end of the sensor holding member 21 in the height direction is less than the thickness of the tip end of the pickup hand 11a and the return hand 11b in the height direction. The sensor holding member 21 is provided for the purpose of making a measurement as to whether the pickup hand 11a and the return hand 11b can be advanced between the substrates. Therefore, the sensor holding member 21 may be able to be advanced into the space between the substrate W, where the pickup hand 11a or the return hand 11b cannot. By reducing the thickness of the sensor holding member 21, the sensor holding member 21 can be advanced into a smaller space. By contrast, the pickup hand 11a and the return hand 11b have a sufficient thickness. With this, the pickup hand 11a and the return hand 11b can hold and transfer the substrate W reliably.

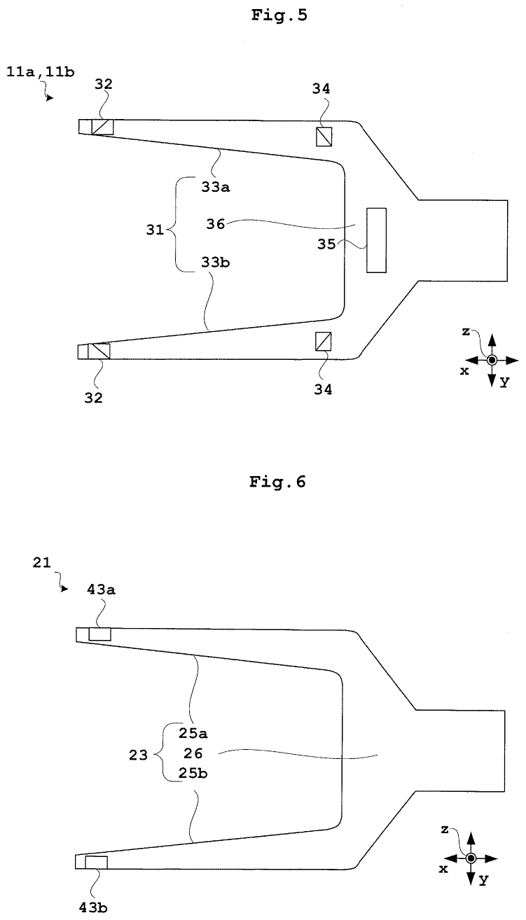

FIG. 5 is a plan view for explaining the pickup hand 11a and the return hand 11b. Each of the pickup hand 11a and the return hand 11b includes a base end 36, and a first holding body 33a and a second holding body 33b that are branched out from the base end 36. The first holding body 33a is a member extending in the front-back direction X and holding one end of the substrate W, and the second holding body 33b is a member extending in the front-back direction X and holding the other end of the substrate W. The guide members 32 are provided at the tip ends of the first holding body 33a and of the second holding body 33b, respectively.

Guide members 34 are provided on the base ends of the first holding body 33a and of the second holding body 33b, respectively. In the same manner as the guide members 32 described above, each of the guide members 34 includes a thick portion having a wall with which the end (bevel portion) of the substrate W can come into contact, and a thin portion having a flat portion with which the peripheral portion of the bottom of the substrate can come into contact. The thick portion of the guide member 34 has the same thickness as the thick portion of the guide member 32. The thin portion of the guide member 34 has the same thickness as the thin portion of the guide member 32. The walls of the guide members 32 and the guide members 34 are provided at positions belonging to a virtual circle that is slightly larger than the substrate W. As a result, the substrate W can fit inside the area for receiving the substrate W, the area being delineated by the thin portions of the guide members 32 and of the guide members 34.

A pusher 35 is provided to the tip end of the base end 36, and can push the substrate W held by the guide members 32 and the guide members 34 in the frontward direction. The pusher 35 is enabled to open by moving rearwards, and to close by moving in the frontward direction. In order for the first holding body 33a and the second holding body 33b to hold the substrate W, to begin with, the guide members 32 and the guide members 34 are caused to hold the substrate W, with the pusher 35 opened. The pusher 35 is then closed, so as to nip the substrate W between the guide members 32 and the pusher 35. The substrate W is gripped in the manner described above.

FIG. 6 is a plan view illustrating the sensor holding member 21. The sensor holding member 21 includes a first projection 25a and a second projection 25b branched out from the base end 26. The first projection 25a and the second projection 25b are members extending in the front-back direction X. The sensor holding member 21 includes at least two sensor groups 43 each group of which includes the first sensor 41 and the second sensor 42. In other words, a first sensor group 43a is provided at the tip end of the first projection 25a. A second sensor group 43b is provided at the tip of the second projection 25b.

As can be seen with reference to FIGS. 5 and 6, the sensor holding member 21 has the same configuration as the pickup hand 11a and the return hand 11b. In other words, the sensor holding member 21 includes the first projection 25a corresponding to the first holding body 33a and extending in the front-back direction X, and a second projection 25b corresponding to the second holding body 33b and extending in the front-back direction. Therefore, the first projection 25a of the sensor holding member 21 and the first holding bodies 33a of the pickup hand 11a and the return hand 11b are at the same position in the width direction. The first sensor group 43a on the first projection 25a measures the distance between the substrate W to be transferred and the substrate W below the substrate to be transferred, at the position where the first holding body 33a advances. In the same manner, the second projection 25b of the sensor holding member 21 and the second holding bodies 33b of the pickup hand 11a and the return hand 11b are at the same position in the width direction. The second sensor group 43b on the second projection 25b measures the distance between the substrate W to be transferred and the substrate W below the substrate to be transferred, at the position from which the second holding body 33b advances.

As can be seen with reference to FIGS. 3, 4A, and 4B, according to this example, the first sensor 41 and the second sensor 42 are provided at the same position of the first projection 25a in the front-back direction X, and the first sensor 41 and the second sensor 42 are provided at the same position of the second projection 25b in the front-back direction X. With this configuration, it is possible to measure the distance between the substrate W to be transferred and the sensor holding member 21, and the distance between the substrate W below the substrate to be transferred and the sensor holding member 21 at the same position in the front-back direction X. Therefore, the minimum distance between the substrates can be measured accurately.

### 3. Operation of Indexer Robot

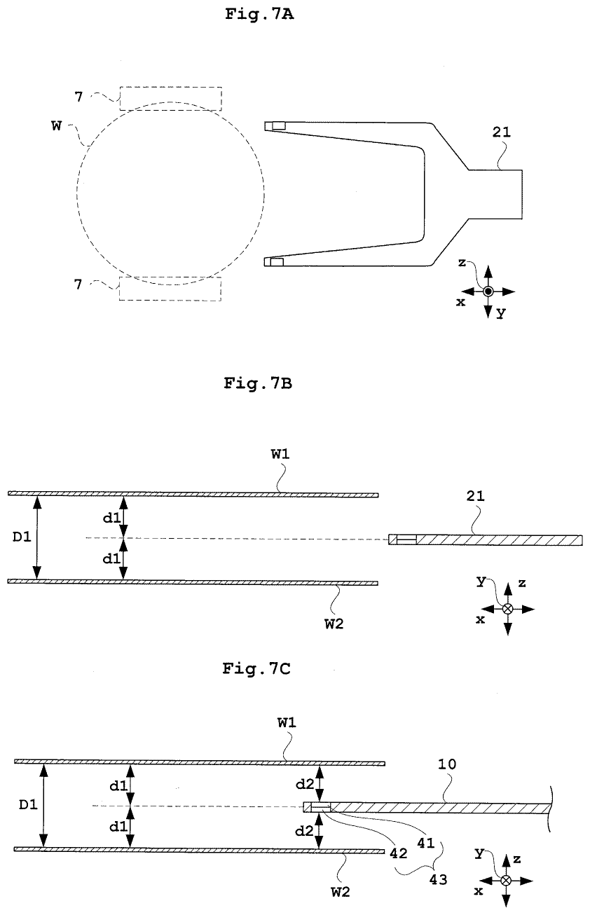

An operation of the indexer robot IR will now be described. In order to transfer the substrate W, to begin with, as illustrated in FIG. 7A, the indexer robot IR moves the arm 12 in the width direction Y to match the position of the sensor holding member 21 with the position of the substrate W in the width direction Y. By moving the pickup hand 11a in the frontward direction X from this position, the pickup hand 11a can be brought closer to the substrate W in the carrier C. In this example, before the pickup hand 11a is moved in the frontward direction X, the minimum distance between the substrates is measured, by advancing the sensor holding member 21 between the substrates.

The indexer robot IR then moves the arm 12 in the vertical direction Z, as illustrated in FIG. 7B, to bring the sensor holding member 21 to the height at the midpoint between the first substrate W1 being the substrate to be transferred and the second substrate W2 positioned below the first substrate W1. As this midpoint height, a height position set in advance for each substrate W is stored in the storage unit attached to a control unit 100 of the device. The first substrate W1 and the second substrate W2 in FIG. 7B are flat without any warpage. Therefore, the minimum distance between the substrates is constant regardless of the positions in the front-back direction X. The distance D1 is the ideal minimum distance between substrates defined by the comb-like member 7 of the carrier C. Specifically, the distance D1 is the length obtained by subtracting the thickness of the substrate W defined in its standard, from the distance between the protrusions of the comb-like member 7. The distance between the protrusions of the comb-like member 7 is equal to the distance between the bottom surface of the first substrate W1 and the bottom surface of the second substrate W2. However, required in transferring the first substrate W1 using the pickup hand 11a is the distance between the bottom surface of the first substrate W1 and the top surface of the second substrate W2. The minimum distance between the substrates therefore is shorter than the distance between the protrusions of the comb-like member 7 by the thickness of the second substrate W2. The sensor holding member 21 in FIG. 7B is at a position higher than the second substrate W2 by a distance d1 that is a half the distance D1. The sensor holding member 21 therefore is at the position lower than the first substrate W1 by the distance d1.

A specific position of the sensor holding member 21 in the vertical direction Z will now be described. For the sensor holding member 21, a reference position in the vertical direction Z is defined. The reference position is set to a position corresponding to the midpoint between the top end of the first sensor 41, which will be described later, and the bottom end of the second sensor 42, which will be described later. Therefore, the distance between the top end of the first sensor 41 and the reference position is equal to the distance between the reference position and the bottom end of the second sensor 42.

The indexer robot IR then moves the sensor holding member 21 in the frontward direction X, and starts measuring the minimum distance between the substrates. In other words, the sensor holding member 21 is advanced between the first substrate W1 that is the substrate to be transferred and the second substrate W2 positioned on the lower side of the first substrate W1. The minimum distance between the substrates is then measured on the basis of the sum of a first minimum distance Umim between the substrates W at a first measurement point s1 where the first sensor 41 is closest to the first substrate W1, and a second minimum distance Lmin between the substrate W at a second measurement point s2 at which the second sensor 42 is closest to the second substrate W2. Specifically, the sensor holding member 21 keeps measuring the minimum distance between the substrates at each position along a line extending in the front-back direction X, while advancing from the rear end toward the front end of the first substrate W1, as illustrated in FIG. 7C. More specifically, the first sensor 41 emits the measurement wave from the top surface of the first sensor 41, and recognizes the distance between the first sensor 41 and the first substrate W1 as d2. In the same manner, the second sensor 42 measures the distance between the second sensor and the second substrate W2 by emitting a measurement wave from the bottom surface of the second sensor 42. In FIG. 7C, because the first substrate W1 and the second substrate W2 are flat, the distance with respect to the first substrate W1 measured by the first sensor 41 remains constant at d2, at any positions in the front-back direction X. In addition, because the sensor holding member 21 is advanced at the midpoint between the first substrate W1 and the second substrate W2, the distance between the first substrate W1 and the first sensor 41 is equal to the distance between the second substrate W2 and the second sensor 42. Hence, the second sensor 42 recognizes the distance between the second sensor 42 and the second substrate W2 as d2. The distance with respect to the second substrate W2 measured by the second sensor 42 remains constant at d2, at any position in the front-back direction X.

The minimum distance between the substrates can be calculated on the basis of the data output from the first sensor 41 and the data output from the second sensor 42. In other words, the minimum distance between the substrates is equal to the sum of d2 that is the first minimum distance Umin between the first sensor 41 and the first substrate W1, d2 that is the second minimum distance Lmin between the second sensor 42 and the second substrate W2, and the thickness of the sensor group 43. In FIG. 7C, this minimum distance between the substrates is calculated as distance D1.

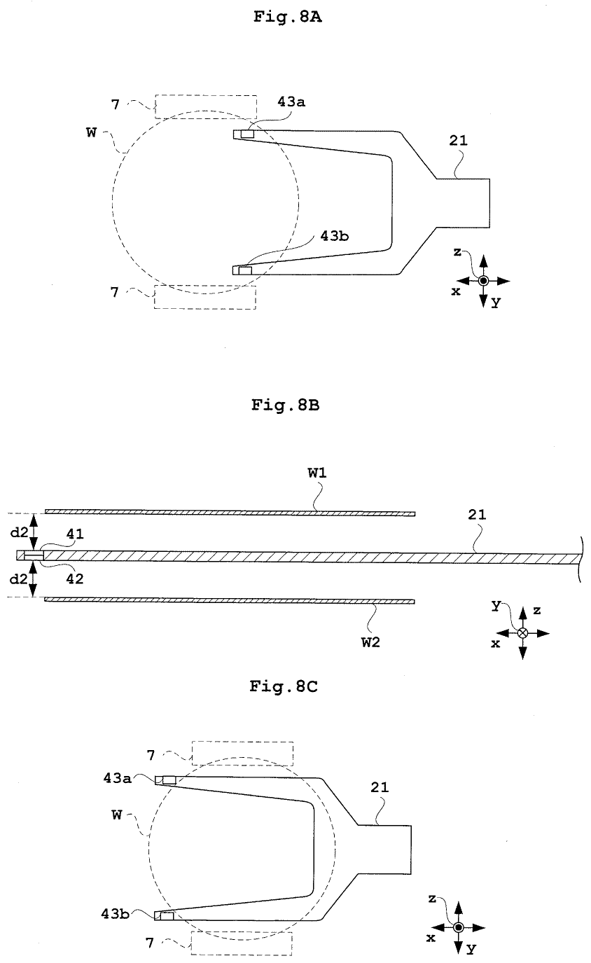

FIG. 8A is a plan view illustrating the sensor holding member 21 at the position in FIG. 7C. In this drawing, the sensor group 43 measures the minimum distance between the rear ends of the substrates W. FIG. 8B illustrates the position of the sensor group 43 having finished measuring the minimum distance between the front ends of the substrates W. The sensor group 43 at this time is at a position protruding from the front end of the substrate W. FIG. 8C is a plan view illustrating the sensor holding member 21 at the position in FIG. 8B. In this drawing, the sensor holding member 21 appears to overlap with the substrates W. The sensor holding member 21 is then retracted, and the pickup hand 11a is then advanced between the first substrate W1 and the second substrate W2. Specifically, the indexer robot IR moves the arm 12 in the vertical direction Z, to bring the sensor holding member 21 to the height at the midpoint between the first substrate W1 being the substrate to be transferred and the second substrate W2 positioned below the first substrate W1.

At this time, the amount by which the arm 12 is moved in the vertical direction Z is determined based on the actual measurement of the minimum distance between the substrates, measured by the sensor holding member 21. In other words, when the pickup hand 11a is advanced between the first substrate W1 and the second substrate W2, the height at which the pickup hand 11a is advanced is adjusted on the basis of the minimum distance between the substrates in such a manner that a predetermined distance is ensured both between the pickup hand 11a and the first substrate W1, and between the pickup hand 11a and the second substrate W2. Specifically, the height at which the pickup hand 11a is advanced is adjusted in such a manner that the distance between the pickup hand 11a and the first substrate W1 becomes equal to the distance between the pickup hand 11a and the second substrate W2.

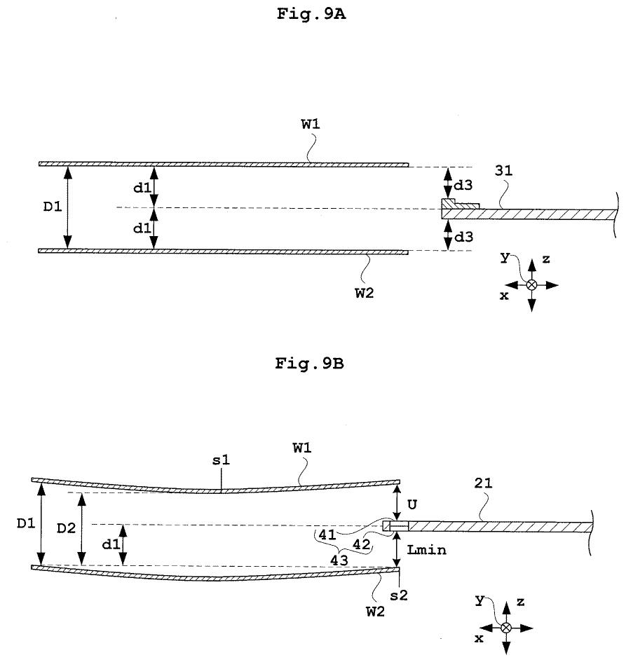

FIG. 9A illustrates the pickup hand 11a after the adjustment of the height at which the pickup hand 11a is advanced, on the basis of the actual measurement of the minimum distance between the substrates. The actual measurement of the minimum distance between the substrates is the distance D1. The arm 12 adjusts the height of the pickup hand 11a in such a manner that the distance between the bottom surface of the pickup hand 11a and the top surface of the second substrate W2 becomes equal to the distance between the top surface of the thick portion of the guide member 32 on the pickup hand 11a and the bottom surface of the first substrate W1. When the minimum distance between the substrates is D1, as indicated in FIG. 9A, the reference position of the pickup hand 11a is positioned higher than the second substrate W2 by d1 that is a half the minimum distance D1 between the substrates. The protrusion of the comb-like member 7 of the carrier C is at the same height as the bottom end of the second substrate W2. An actual measurement of the thickness of the second substrate W2 can be obtained by referring to the distance measured by the second sensor 42. Therefore, the reference position of the pickup hand 11a is matched to the height resultant of adding d1, which is about a half the actually measured distance D1, to the height of the top end of the protrusion supporting the second substrate W2, plus the thickness of the second substrate W2. The reference position of the pickup hand 11a in the vertical direction Z is set to the position at the middle of the pickup hand 11a having a predetermined thickness. The length of the thick portion of the guide member 32 between the reference position and the top end is equal to the length between the reference position and the bottom end of the hand body 31. Therefore, the reference position corresponds to the midpoint between the top end of the thick portion of the guide member 32 and the bottom end of the hand body 31.

The arm 12 then moves the pickup hand 11a having the position established in the vertical direction Z in the frontward direction, and is advanced between the substrates, along the midpoint between the substrates. At this time, the distance between the first substrate W1 and the thick portion of the guide member 32 of the pickup hand 11a is d3. The distance between the second substrate W2 and the bottom end of the hand body 31 of the pickup hand 11a is also d3. In this example, the reference position of the pickup hand 11a is established with reference to the thick portion of the guide member 32. This portion is the thickest portion of the pickup hand 11a. According to this example, the guide member 32 positioned at the tip end of the pickup hand 11a is set particularly not to collide with the substrate W. The guide member 32 is the part of in the pickup hand 11a that is most likely to collide with the substrate W. According to this example, optimization is made to avoid collision of the guide member 32 with the substrate W.

When the front end of the pickup hand 11a reaches the front end of the first substrate W1, the pickup hand 11a is lifted by a predetermined amount, to move the first substrate W1 above the comb-like member 7. At this time, the end (bevel portion) of the first substrate W1 is at the position facing the wall portions of the thick portions of the guide member 32 and the guide member 34. The pusher 35, which has been open up to this point in time, is then closed, and causes the pickup hand 11a to grip the first substrate W1. As the pickup hand 11a is moved rearwards, the first substrate W1 is pulled out of the carrier C, accordingly. The first substrate W1 is transferred in the manner described above.

### 4. Operation of Indexer Robot (With Warped Substrate)

FIG. 9B illustrates an example in which the first substrate W1 that is the substrate to be transferred, and the second substrate W2 are both warped, unlike the example illustrated in FIG. 7B. According to this example, such a first substrate W1 can also be transferred suitably. In order to transfer the first substrate W1, to begin with, the indexer robot IR moves the arm 12 in the vertical direction Z, as illustrated in FIG. 9B, and positions the sensor holding member 21 at the height corresponding to the midpoint between the first substrate W1, which is the substrate to be transferred, and the lower second substrate W2, in the same manner as in FIG. 7B. The distance D1 is the ideal minimum distance between substrates defined by the comb-like member 7 of the carrier C. Specifically, the distance D1 is the length obtained by subtracting the thickness of the substrate W defined in its standard, from the distance between the protrusions of the comb-like member 7. The sensor holding member 21 in FIG. 9B is at a position higher than the second substrate W2 by the distance d1 that is a half the distance D1. The sensor holding member 21 therefore is at the position lower than the first substrate W1 by the distance d1.

The position of the sensor holding member 21 is thus determined on the basis of the ideal minimum distance between the substrates. Therefore, the measurement of the minimum distance between the substrates, which is measured by the sensor holding member 21, is not necessarily equal to the distance D1, which is an ideal value. Nevertheless, at the ends of the substrate, the minimum distance between the substrates can be considered as the distance D1. This is because the peripheral portions of the substrates W are held by the comb-like member 7 of the carrier C. One example of the warpage of the first substrate W1 is a bowl-like warpage recessed at the center of the substrate W. One example of warpage of the second substrate W2, too, is a bowl-like warpage, in the same manner as the first substrate W1. With such warpage, because the first substrate W1 and the second substrate W2 are rotating bodies, the left and right ends of the substrate W held on the comb-like member 7 are the same height as the height of the front end and the rear end of the substrate W not held on the comb-like member 7. Therefore, the distance between the substrates at the substrate ends is indicated as the distance D1, in FIG. 9B.

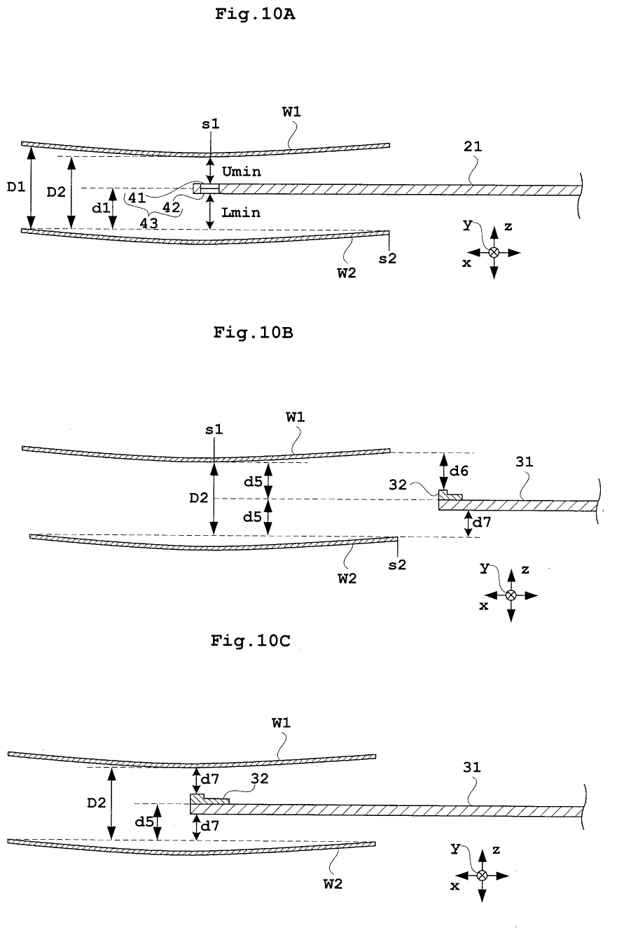

However, because the first substrate W1 is warped, a distance U between the first sensor 41 and the first substrate W1 changes depending on the position on the first substrate W1. FIG. 10A illustrates the positioning after the tip end of the sensor holding member 21 has arrived at the central portion of the first substrate W1. At this point, the first sensor 41 is closest to the first substrate W1. In other words, the distance between the first sensor 41 and the first substrate W1 equals to a first minimum distance Umin. This point of the first substrate W1 where the distance between the first sensor 41 and the first substrate W1 equals to the first minimum distance Umin will be referred to as a first measurement point s1.

In the same manner, because the second substrate W2 is warped, the distance L between the second sensor 42 and the second substrate W2 changes depending on the position on the second substrate W2. FIG. 9B illustrates the positioning in which the tip end of the sensor holding member 21 is positioned at the tip end of the first substrate W1. At this point, the second sensor 42 is closest to the second substrate W2. In other words, the distance between the second sensor 42 and the second substrate W2 equals to a second minimum distance Lmin. The position of the second substrate W2 at which the distance between the second sensor 42 and the second substrate W2 is equal to the second minimum distance Umin will be referred to as a second measurement point s2.

The first sensor 41 in the sensor holding member 21 according to this example measures the distance while being moved from the end of the first substrate W1 at the opening of the carrier C, toward the back of the carrier C. In the same manner, the second sensor 42 measures the distance while being moved from the end of the second substrate W2 at the opening of the carrier C, toward the back of the carrier C. The first sensor 41 in this example, however, measures the distance while being moved from the rear end toward the tip end of the first substrate W1. In the same manner, the second sensor 42 measures the distance while being moved from the rear end toward the tip end of the second substrate W2. The first sensor 41 and the second sensor 42 then measure the minimum distance between the substrates based on the distance between the substrates at the first measurement point s1 and the distance between the substrates at the second measurement point s2.

The minimum distance D2 between the two substrates W1 and W2 herein is the minimum distance, in the height direction, between the first substrate W1 and the second substrate W2 when the first substrate W1 and the second substrate W2 are viewed from the direction along which the sensor holding member 21 is advanced between the substrates (in other words, the direction from the rear end to the front end in the X direction). The distance in the height direction between the two substrates W1 and W2 herein means a distance between the lowest part of the upper substrate W1 (the lowermost portion: the first measurement point s1) and the highest part of the lower substrate W2 (the uppermost portion: the second measurement point s2). For example, when the upper substrate W1 and the lower substrate W2 are warped as illustrated in FIG. 10A, the lowest part of the upper substrate W1 corresponds to the part detected as having the minimum distance d4 between the first sensor 41 and the first substrate W1. In FIG. 10A, the central portion of the substrate W1 is the lowest part of the substrate W1. By contrast, the highest part of the lower substrate W2 corresponds to the part detected as having the minimum distance d2 between the second sensor 42 and the second substrate W2. In FIG. 10A, the highest part of the substrate W2 is the rearmost part of the substrate W2 in the X direction. The sum of the minimum distance d4 and the minimum distance d2 is the minimum distance D2 between the two substrates W1 and W2.

When the measurement between the substrates is completed, the sensor holding member 21 is moved in the rearward direction, and, this time, the pickup hand 11a is then advanced between the substrates. At this time, the height at which the pickup hand 11a is advanced is adjusted in such a manner that the distance between the pickup hand 11a and the first substrate W1 becomes equal to the distance between the pickup hand 11a and the second substrate W2. In order to calculate the height at which the pickup hand 11a is advanced, the minimum distance D2 between the substrate distance is referred to.

When the pickup hand 11a is advanced between the first substrate W1 and the second substrate W2, the pickup hand 11a is most likely to collide with the first substrate W1 at the first measurement point s1. When the pickup hand 11a is advanced between the first substrate W1 and the second substrate W2, the pickup hand 11a is most likely to collide with the second substrate W2 at the second measurement point s2. In the substrate transfer apparatus according to the present embodiment, the height at which the pickup hand 11a is advanced is adjusted in such a manner that the substrate W is least likely to collide with the pickup hand 11a at both the first measurement point s1 and the second measurement point s2.

FIG. 10B illustrates the pickup hand 11a after the adjustment of the height at which the pickup hand 11a is advanced, on the basis of the actual measurement of the minimum distance between the substrates. The actual measurement of the minimum distance between the substrates is D2. The arm 12 adjusts the height of the pickup hand 11a in such a manner that the distance between the bottom surface of the pickup hand 11a and the top surface of the second substrate W2 (to generalize, the highest part of the second substrate W2) becomes equal to the distance between the top surface of the thick portion of the guide member 32 on the pickup hand 11a and the bottom surface of the first substrate W1 (to generalize, the lowest part of the first substrate W1). The arm 12 adjusts the height of the pickup hand 11a in such a manner that the distance between the first substrate W1 and the pickup hand 11a becomes d5 at the first measurement point s1, where the first substrate W1 and the pickup hand 11a are closest to each other. The arm 12 then adjusts the height of the pickup hand 11a in such a manner that the distance between the second substrate W2 and the pickup hand 11a becomes d5 at the second measurement point s2, where the second substrate W2 and the pickup hand 11a are closest to each other. In other words, when the minimum distance between the substrates is D2, as indicated in FIG. 10B, the reference position of the pickup hand 11a is set to the position higher than the second substrate W2 by d5 that is about a half the minimum distance D2 between the substrates. The protrusion of the comb-like member 7 of the carrier C is at the same height as the bottom end of the second substrate W2. An actual measurement of the thickness of the second substrate W2 can be obtained by referring to the distance measured by the second sensor 42. Therefore, the reference position of the pickup hand 11a is matched to the height resultant of adding d5, which is about a half the actually measured minimum distance D2, to the height of the top end of the protrusion supporting the second substrate W2, plus the thickness of the second substrate W2. As described above, in this example, the height at which the pickup hand 11a is advanced is adjusted in such a manner that the distance between the pickup hand 11a and the lowest part of the first substrate W1 becomes equal to a predetermined distance or more at the first measurement point s1 where the lowest part of the first substrate W1 and the first sensor 41 are closest to each other. In the same manner, the height at which the pickup hand 11a is advanced is adjusted in such a manner that the distance between the pickup hand 11a and the highest part of the second substrate W2 becomes equal to or more than the predetermined distance at the second measurement point s2 where the highest part of the second substrate W2 and the second sensor 42 are closest to each other.

The arm 12 then moves the pickup hand 11a having the position established in the vertical direction Z in the frontward direction, and is advanced between the substrates, along the midpoint between the substrates. At this time, the distance between the first substrate W1 and the thick portion of the guide member 32 in the pickup hand 11a is d6. The distance between the second substrate W2 and the bottom end of the hand body 31 of the pickup hand 11a is d7 that is shorter than d6. As the tip end of the pickup hand 11a advances between the substrates, the first substrate W1 gradually becomes closer to the tip end of the pickup hand 11a. Specifically, the distance between the tip end of the pickup hand 11a and the first substrate W1 becomes shorter toward d7, starting from d6 as an initial value. This is because the first substrate W1 has a warped shape toward the second substrate W2. By contrast, even if the tip end of the pickup hand 11a is advanced between the substrates, the second substrate W2 does not become closer to the tip end of the pickup hand 11a. Therefore, the distance between the tip of the pickup hand 11a and the second substrate W2 does not become less than d7. FIG. 10C illustrates the positioning in which the first substrate W1 is at the position closest to the tip end of the pickup hand 11a. In other words, the distance between the bottom end of the first substrate W1 and the top end of the thick portion of the guide member 32 is d7, and the distance from the bottom end of the hand body 31 and the top end of the second substrate W2 is longer than d7. Because d7 is equal to or more than the distance required for transferring a substrate, the pickup hand 11a collides with neither the first substrate W1 nor the second substrate W2 while the pickup hand 11a is advanced between the substrates.

As the pickup hand 11a further extends from the position illustrated in FIG. 10C and reaches the front end of the first substrate W1, the distance between the first substrate W1 and the tip end of the pickup hand 11a increases from d7. Therefore, even during this operation, too, the pickup hand 11a collides with neither the first substrate W1 nor the second substrate W2.

5. Operation of Indexer Robot (when Pickup Hand Cannot be Advanced)

In this example, if it is found that, as a result of the minimum distance measurement between the substrates, the distance between the first substrate W1 and the second substrate W2 is too short to ensure a distance equal to or more than the predetermined distance between the pickup hand 11a and the first substrate W1 at the first measurement point s1, and between the pickup hand and the second substrate W2 at the second measurement point s2
at the same time, the pickup hand 11a is not allowed to be advanced between the first substrate W1 and the second substrate W2.

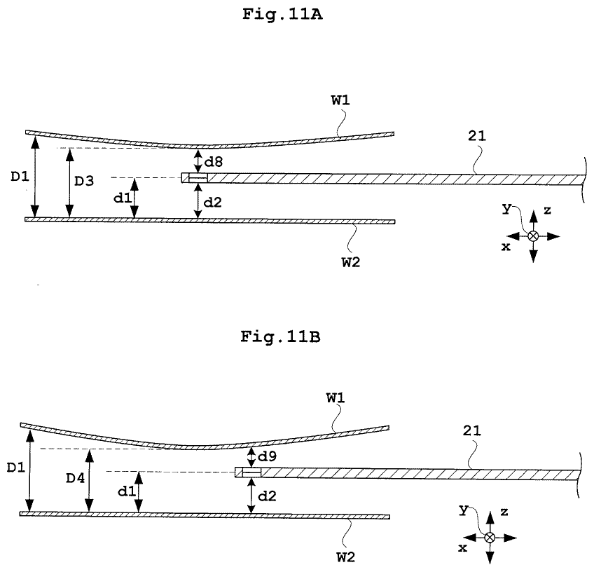

FIG. 11A illustrates an example in which the minimum distance between the substrates is D3. The minimum distance D3 is even shorter than the minimum distance D2 described above, and the first substrate W1 is warped more extensively than that in FIG. 9B by that much. An operation of the indexer robot IR in such a case will now be described.

To begin with, the indexer robot IR moves the arm 12 in the vertical direction Z, to bring the sensor holding member 21 to the height at the midpoint between the first substrate W1 being the substrate to be transferred and the second substrate W2 positioned below the first substrate W1. The distance D1 is the ideal distance between substrates defined by the comb-like member 7 of the carrier C. Specifically, the distance D1 is the length obtained by subtracting the thickness of the substrate W defined in its standard, from the distance between the protrusions of the comb-like member 7. The sensor holding member 21 is set at a position higher than the second substrate W2 by the distance d1 that is a half the distance D1. The sensor holding member 21 therefore is at the position lower than the first substrate W1 by a distance d8.

Because the first substrate W1 is warped, the minimum distance between the substrates changes depending the position on the substrates W. FIG. 11A illustrates the positioning after the tip end of the sensor holding member 21 has arrived at the central portion of the first substrate W1. At this point, the first sensor 41 is closest to the first substrate W1. In other words, the distance between the first sensor 41 and the first substrate W1 is d8. By contrast, because the second substrate W2 is flat, the distance between the second sensor 42 and the second substrate W2 is d2. The sensor holding member 21 measures the minimum distance D3 between the first substrate W1 and the second substrate W2, on the basis of d8 and d2. In other words, the minimum distance D3 is the distance obtained by adding d8 and d2 to the thickness of the sensor group 43 in the vertical direction Z. The part where the substrates are close to each other by the minimum distance D3 is where the pickup hand 11a is most likely to collide when the substrate is transferred.

The minimum distance D3 is shorter than the length obtained by adding the thickness of the pickup hand 11a to twice the predetermined distance, and therefore, it is not possible to ensure a distance equal to or more than the predetermined distance between the pickup hand 11a and the first substrate W1, and between the pickup hand 11a and the second substrate W2, at the same time. In this case, the indexer robot IR in this example does not advance the pickup hand 11a into between the first substrate W1 and the second substrate W2. In this manner, collision between the first substrate W1 and the pickup hand 11a during transfer of the first substrate W1 can be avoided.

6. Operation of Indexer Robot (when Sensor Holding Member Cannot be Advanced)

In this example, as a result of measuring the minimum distance between the substrates, when the distance between the first substrate W1 and the second substrate W2 is too short to advance the sensor holding member 21 between the first substrate W1 and the second substrate W2, the pickup hand 11a is not advanced between the first substrate W1 and the second substrate W2.

FIG. 11B illustrates an example in which the minimum distance between the substrates is D4. The minimum distance D4 is even shorter than the minimum distance D3 described above, and the first substrate W1 is warped more extensively than that in FIG. 11A by that much. An operation of the indexer robot IR in such a case will now be described.

To begin with, the indexer robot IR moves the arm 12 in the vertical direction Z, to bring the sensor holding member 21 to the height at the midpoint between the first substrate W1 being the substrate to be transferred and the second substrate W2 positioned below the first substrate W1. The distance D1 is the ideal minimum distance between substrates defined by the comb-like member 7 of the carrier C. Specifically, the distance D1 is the length obtained by subtracting the thickness of the substrate W defined in its standard, from the distance between the protrusions of the comb-like member 7. The sensor holding member 21 is set at a position higher than the second substrate W2 by the distance d1 that is a half the distance D1. The sensor holding member 21 therefore is at the position lower than the first substrate W1 by the distance d1.

Because the first substrate W1 is warped, the minimum distance between the substrates changes depending the position on the substrates W. FIG. 11B illustrates the positioning after the tip end of the sensor holding member 21 has arrived at the central portion of the first substrate W1. At this time, before arriving at the position closest to the first substrate W1, the distance between the first sensor 41 and the first substrate W1 reaches d9. By contrast, because the second substrate W2 is flat, the distance between the second sensor 42 and the second substrate W2 is d2. The substrate transfer apparatus in this example is configured to stop measuring the minimum distance between the substrates, and retract the sensor holding member 21 at the timing at which the distance between the first sensor 41 and the first substrate W1 reaches d9. In the same manner, when the distance between the second sensor 42 and the second substrate W2 reaches d9, the substrate transfer apparatus according to this example stops measuring the minimum distance between the substrates, and retracts the sensor holding member 21. With such a configuration, the sensor holding member 21 does not collide with the substrate W.

FIG. 11B illustrates the example in which the advancement of the sensor holding member 21 is stopped because the first sensor 41 becomes too close to the first substrate W1. In the same manner, the sensor holding member 21 is stopped being advanced when the distance between the second substrate W2 and the second sensor 42 reaches d9 due to the warpage of the second substrate W2.

When the sensor holding member 21 fails to be advanced between the first substrate W1 and the second substrate W2, because the sensor holding member 21 is retracted, the pickup hand 11a is not allowed to be advanced between the first substrate W1 and the second substrate W2, either. In other words, when the distance d9 is detected either by the first sensor 41 or by the second sensor, it is determined not to cause the pickup hand 11a to transfer the first substrate W1. In this manner, collision between the first substrate W1 and the pickup hand 11a during transfer of the first substrate W1 can be avoided.

### 7. Other Configurations

As can be seen with reference to FIG. 1, the substrate transfer apparatus according to this example includes a control unit 100. The control unit 100 is implemented as a central processing unit (CPU), for example. As a specific configuration of the control unit 100, the control unit 100 may be implemented as a single processor, or individual processors, for example, but without limitation thereto.

Examples of control related to the control unit 100 include control related to the indexer robot IR. In other words, the control unit 100 controls the operation of advancing and retracting the sensor holding member 21, the operation of advancing and retracting the pickup hand 11a and the return hand 11b, the operation of opening and closing the pusher 35, the movement of the arm 12 in the vertical direction Z, a mapping sensor, to be described later, and an actuator mechanism for the mapping sensor. In particular, the control unit 100 is configured to advance and to retract the pickup hand 11a, the return hand 11b, and the sensor holding member 21 with respect to the substrates W in the front-back direction.

Although not illustrated in FIG. 1, the substrate transfer apparatus according to this example includes a storage unit that is accessible by the control unit 100. The storage unit stores therein programs, parameters, and the like. Furthermore, the storage unit stores therein the minimum distance between the substrates, measured by the sensor holding member 21 described above, and the like. The storage unit may be configured as a single device, or may be configured as individual devices corresponding to the respective control units. Furthermore, the substrate transfer apparatus according to this example has no particular limitation as to the configuration of the device for implementing the storage unit.

### 8. Sequence of Substrate Transfer

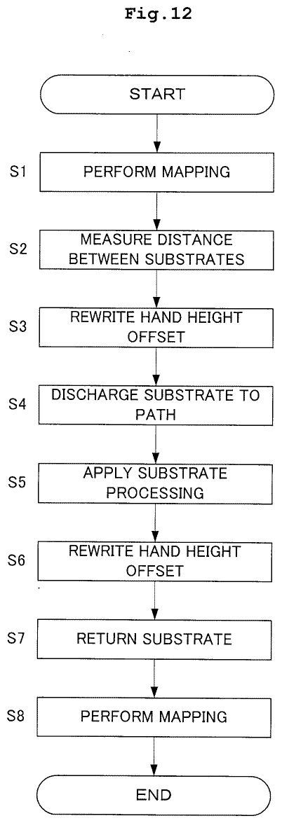

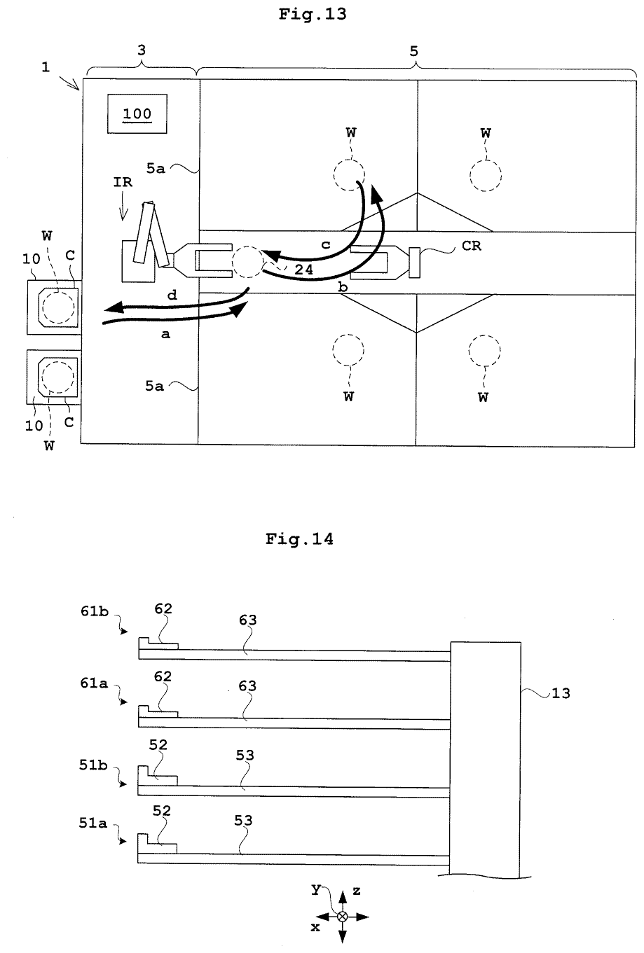

FIG. 12 is a flowchart of an operation for explaining the substrate transfer apparatus according to the present invention. An operation of the substrate transfer apparatus performed when the substrate processing apparatus 1 according to the present invention performs a substrate cleaning process will now be described. FIG. 13 illustrates how the substrate W is transferred inside the substrate processing apparatus 1. In the following description, FIG. 13 is also referred to, as appropriate.

Step S1: When the carrier C to be processed is placed at the load port 10, the substrate transfer apparatus starts a mapping operation of the substrates W. The substrate transfer apparatus includes a mapping sensor for performing this operation, and the actuator mechanism for the mapping sensor. The actuator mechanism can move the mapping sensor in the vertical direction Z. The mapping sensor is a non-contact sensor, and can sense the presence of the substrates W. Specifically, the mapping operation is performed by moving the mapping sensor in the vertical direction Z with respect to the carrier C. As a result, it is possible to recognize which parts of the comb-like member 7 of the carrier C the substrates W are placed. The mapping operation is an operation for acquiring the distribution of the substrates W in the carrier C.

Step S2: The indexer robot IR is moved to the rear side of the carrier C, and the sensor holding member 21 is advanced into the carrier C. If the substrates W are supported by the comb-like member 7 at an interval of 1 cm, the sensor holding member 21 is advanced between the substrates W. 1 cm is the pitch at which the protrusions are provided to the comb-like member 7. When 25 substrates W are arranged at the interval of 1 cm in the carrier C, the sensor holding member 21 is advanced into each of the twenty four spaces between the substrates, one after another. The minimum distance between the substrates, obtained by the sensor holding member 21 is stored in the storage unit. If the substrate W is supported by the carrier C at an interval of 2 cm or more, it can be said that the minimum distance between the substrates is sufficient for transferring a substrate even without making a measurement. Therefore, the operation of advancing the sensor holding member 21 may be skipped. It is possible to recognize how the substrates W are arranged in the carrier C by referring to the result of the mapping operation.

Step S3: The height of the reference position in the pickup hand 11a is determined, on the basis of the result of measuring the distance between the substrates, having been measured by the sensor holding member 21. Parameters related to the control of the pickup hand 11a are changed so as to bring the reference position of the pickup hand 11a to the determined height. Specifically, this operation is implementing by rewriting a hand height offset value for defining the height of the pickup hand 11a.

Step S4: The arm 12 of the indexer robot IR is moved in the vertical direction, and positions the pickup hand 11a at the height of the substrate W to be transferred. The height of the pickup hand 11a at this time is a height suitable for transferring the substrate W to be transferred. The pickup hand 11a grips the substrate W to be transferred, and discharges the substrate W onto the path 24 (see the arrow a in FIG. 13).

Step S5: The unprocessed substrate W held on the path 24 is transferred to the single-wafer processing chamber 5a by the center robot CR (see an arrow b in FIG. 13). The single-wafer processing chamber 5a performs cleaning processing on the substrate W. The processed substrate W is then transferred to the path 24 by the center robot CR (see an arrow c in FIG. 13).

Step S6: The cleaned substrate W having been subjected to the cleaning processing is transferred by the return hand 11b. To begin with, the height for bringing the reference position in the return hand 11b is determined on the basis of the result of measuring the distance between the substrates, having been measured by the sensor holding member 21. In other words, parameters related to the control of the return hand 11b are changed so as to bring the reference position of the return hand 11b to the determined height. Specifically, this operation is implementing by rewriting a hand height offset value for defining the height of the return hand 11b.

The hand height offset value related to the pickup hand 11a can be reused for rewriting the hand height offset value related to the return hand 11b. Each of the substrates W having been held in the carrier C is returned, after the substrate processing, in the same order in the carrier C. Therefore, the same height is used in causing the return hand 11b to return the substrate W into the carrier C, as that used by the pickup hand 11a in picking up the substrate W from the carrier C. The height of the pickup hand 11a is a value unique to each of the substrates W held in the carrier C. In the process of returning the substrate W to the carrier C, the operation of the pickup hand 11a is reproduced by the return hand 11b, on the basis of the unique values. In this manner, the tip of the return hand 11b is also prevented from colliding with the substrate W in the process of returning the substrate W.

Step S7: The return hand 11b picks up the substrate W to be transferred from the path 24. The arm 12 of the indexer robot IR is moved in the vertical direction, and positions the return hand 11b at the height determined in step S6. The return hand 11b having placed the substrate W on the carrier C and returning to the substrate transfer apparatus is at the same height as that when the pickup hand 11a picks up the substrate W from the carrier C. This is because the pickup hand 11a and the return hand 11b operate on the basis of the common hand height offset value. The return hand 11b transfers the substrate W to be transferred from the path 24 to the carrier C (see an arrow d in FIG. 13). The substrate W having been resting on a certain protrusion in the comb-like member 7 of the carrier C is returned to the same protrusion through the substrate pick-up operation and the substrate return operation.

Step S8: Upon completing returning the substrate W into the carrier C, the substrate transfer apparatus repeats the mapping operation of the substrate W as in step S1. As a result, the operation of the substrate transfer apparatus according to this example is ended.

Note that the above description of the operations from step S1 to step S8 has focused on one substrate W. Therefore, in a case where a plurality of substrates W are to be transferred from the carrier C and the cleaning process of the substrates W to be performed, steps S3 and S4 may be repeated before the system control goes to step S5. In the same manner, steps S6 and S7 may be repeated before the system goes to step S9.

### 9. Effects Achieved by Embodiment 1

As described above, the substrate transfer apparatus includes the sensor holding member 21 that is provided with the first sensor 41 and the second sensor 42, separately from the pickup hand 11a and the return hand 11b for transferring the substrate W. According to the present invention, when the first substrate W1 in the carrier C is to be transferred, the sensor holding member 21 is advanced between the first substrate W1 and the second substrate W2, to begin with. The sensor holding member 21 then measures the distance between the first substrate W1 and the second substrate W2. Because the positions where substrates W are placed in the carrier C are fixed, the distance between the first substrate W1 and the second substrate W2 should remain constant. However, the first substrate W1 and the second substrate W2 are actually not always flat. Therefore, in the actual measurement of the distance between the first substrate W1 and the second substrate W2, the minimum distance between the substrates may be longer or shorter than expected. At the same time, the position of the midpoint between the substrates may be higher or lower than expected.

According to the present invention, when the pickup hand 11a or the return hand 11b is advanced between the first substrate W1 and the second substrate W2, the height at which the pickup hand 11a or the return hand 11b is advanced is adjusted in such a manner that a predetermined clearance or more is ensured both between the pickup hand 11a or the return hand 11b and the first substrate W1, and between the pickup hand 11a or the return hand 11b and the second substrate W2. With this configuration, it is possible to prevent the pickup hand 11a and the return hand 11b from coming into contact with any portion of the first substrate W1 other than its peripheral portion, by coming too close to the first substrate W1. In the same manner, it is possible to prevent the pickup hand 11a and the return hand 11b from coming into contact with any portion of the second substrate other than its peripheral portion W2, by coming too close to the second substrate W2.

In the configuration described above, the thickness of the tip end of the sensor holding member 21 including the first sensor 41 and the second sensor 42 is less than the thickness of the tip end of the pickup hand 11a and the return hand 11b including the guide member 32. With this configuration, the sensor holding member 21 can be advanced between the substrates between which the pickup hand 11a or the return hand 11b cannot be advanced, and can measure the minimum distance between the substrates, reliably.

In the configuration described above, at the position at which the first substrate W1 and the second substrate W2 are closest to each other, the height at which the pickup hand 11a or the return hand 11b is advanced is adjusted in such a manner that a predetermined clearance or more is ensured both between the pickup hand 11a or the return hand 11b and the first substrate W1, and between the pickup hand 11a or the return hand 11b and the second substrate W2. With this configuration, the pickup hand 11a and the return hand 11b do not come into contact with the substrate W at the position where the first substrate W1 and the second substrate W2 are closest to each other.

In the configuration described above, the height at which the pickup hand 11a and the return hand 11b are advanced are adjusted in such a manner that the clearance between the pickup hand 11a or the return hand 11b and the first substrate W1 becomes equal to the clearance between the pickup hand 11a or the return hand 11b and the second substrate W2. With this configuration, the substrate W can be transferred while a sufficient distance ensured not only between the pickup hand 11a or the return hand 11b and the first substrate W1, but also between the pickup hand 11a or the return hand 11b and the second substrate W2. Therefore, the hand can transfer the substrate W more reliably.

In the configuration described above, the sensor holding member 21 does not transfer the substrate W. With this configuration, it is not necessary to provide the sensor holding member 21 with a guide member 32 for holding the substrate W, and it is possible to advance the sensor holding member between the substrates more smoothly.

In the configuration described above, when the distance between the first substrate W1 and the second substrate W2 is too short to ensure the predetermined clearance or more between the pickup hand 11a or the return hand 11b and the first substrate W1, and between the pickup hand 11a or the return hand 11b and the second substrate W2 at the same time, it is determined that the pickup hand 11a or the return hand 11b is not capable of transferring the first substrate W1, and neither the pickup hand 11a nor the return hand 11b is advanced between the first substrate W1 and the second substrate W2. With this configuration, it is possible to prevent the pickup hand 11a or the return hand 11b from coming into contact with any portion of the substrate W other than its peripheral portion, more reliably.

In the configuration described above, it is possible to reduce the amount by which the first sensor 41 and the second sensor 42 protrude, by the amount corresponding to the thickness of the sensor holding member 21. In this manner, because the height of the sensor holding member 21 can thus be minimized, it is possible to suppress the chances of the sensor holding member 21 not being capable of being advanced between the substrates.

In the configuration described above, the sensor holding member 21 includes the first sensor group 43a that measures the minimum distance between the substrates at the positions corresponding to the first holding bodies 33a of the pickup hand 11a and the return hand 11b, and the sensor holding member 21 includes the second sensor group 43b that measures the minimum distance between the substrates at the positions corresponding to the second holding bodies 33b of the pickup hand 11a and the return hand 11b. In this manner, it is possible to prevent the pickup hand 11a and the return hand 11b from coming into contact with any portion of the substrate W other than its peripheral portion, more reliably.

In the configuration described above, the sensor holding member 21 includes the first projection 25a corresponding to the first holding body 33a and extending in the front-back direction X, and the second projection 25b corresponding to the second holding body 33b and extending in the front-back direction X. By providing the sensor holding member 21 with a shape similar to the shape of the pickup hand 11a and the return hand 11b, it is possible to collect the distance-related information required for the transfer, more reliably.

In the configuration described above, the sensor group 43 is provided to the tip of the first projection 25a of in the sensor holding member 21, and the sensor group 43 is provided to the tip of the second projection 25b of the sensor holding member 21. With this configuration, it is possible to measure the minimum distance between the substrates near the back of the carrier C, by moving the sensor holding member 21 slightly.

In the configuration described above, the sensor holding member 21 includes the first sensor 41 and the second sensor 42 at the same position of the first projection 25a in the front-back direction X. The sensor holding member 21 also includes the first sensor 41 and the second sensor 42 at the same position of the second projection 25b in the front-back direction X. With this configuration, because it is possible to make measurements for the substrate on the upper side of the sensor holding member 21 (first substrate W1) and the substrate on the lower side of the sensor holding member 21 (second substrate W2) under the same condition, the minimum distance between the substrates can be calculated more accurately.

In the configuration described above, when the distance between the first substrate W1 and the second substrate W2 is too short to advance the sensor holding member 21 into the space between the first substrate W1 and the second substrate W2, it is determined that the pickup hand 11a and the return hand 11b cannot transfer the first substrate W1, and the pickup hand 11a and the return hand 11b are not advanced between the first substrate W1 and the second substrate W2. With this configuration, it is possible to prevent the pickup hand 11a or the return hand 11b from coming into contact with any portion of the substrate W other than its peripheral portion, more reliably.

In the configuration described above, the sensor holding member 21 is at the same position as the pickup hand 11a and the return hand 11b in the front-back direction X, before being advanced between the substrates W. With this configuration, the present invention can be achieved by allowing a single robot to use the pickup hand 11a, the return hand 11b, and the sensor holding member 21, selectively.

### Embodiment 2

### 10. Outline of Embodiment 2

Embodiment 2 relates to a substrate transfer apparatus, but in the explanation below, an example of a substrate processing apparatus 1 having the substrate transfer apparatus incorporated therein will be used as an example, in the same manner as in Embodiment 1. As described with reference to FIG. 1, the substrate processing apparatus 1 according to Embodiment 2 includes the load port 10, the indexer block 3, and the processing block 5. In the substrate transfer apparatus according to this example, the indexer robot IR in the indexer block 3 has a different configuration from that in Embodiment 1.

### 11. Configuration of Indexer Robot

FIG. 14 schematically illustrates tip ends involved in holding of a substrate, in the indexer robot TR. The indexer robot IR includes a first pickup hand 51a, a first return hand 51b, a second pickup hand 61a, and a second return hand 61b. The arm 13 holds the first pickup hand 51a, the first return hand 51b, the second pickup hand 61a, and the second return hand 61b on top of one another in the vertical direction Z. The arm 13 can advance and retract the first pickup hand 51a, the first return hand 51b, the second pickup hand 61a, and the second return hand 61b, independently in the front-back direction X. In the configuration illustrated in FIG. 14, the second return hand 61b, the second pickup hand 61a, the first return hand 51b, and the first pickup hand 51a are arranged from the top to the bottom, in the order listed herein, but the order in which these members are arranged may be changed as appropriate.

The first pickup hand 51a corresponds to the first hand according to the present invention, and corresponds to the pickup hand 11a in Embodiment 1. The first pickup hand 51a therefore holds one unprocessed substrate W at a time from the carrier C, and transfers the substrate W onto the path 24. The first pickup hand 51a includes a hand body 53 and a first guide member 52. The first guide member 52 is positioned at the tip end of the first pickup hand 51a, and is configured to abut against the end of the substrate W. The hand body 53 has the same configuration as the hand body 31 according to Embodiment 1. The first guide member 52 has the same configuration as the guide member 32 according to Embodiment 1. The first guide member 52 therefore has a thick portion and a thin portion. The first guide member 52 has parts with different thicknesses in the height direction. The first pickup hand 51a is a hand for a high-speed transfer, and transfers one substrates W at a time, from the carrier C that stores therein a plurality of substrates W in the horizontal postures, with a predetermined interval therebetween in the vertical direction Z.

The first return hand 51b corresponds to the return hand 11b according to Embodiment 1, and has the same configuration as the first pickup hand 51a described above. The first pickup hand 51a is a hand for picking up the unprocessed substrate W from the carrier C, and the first return hand 51b is a hand for returning the cleaned substrate W to the carrier C.

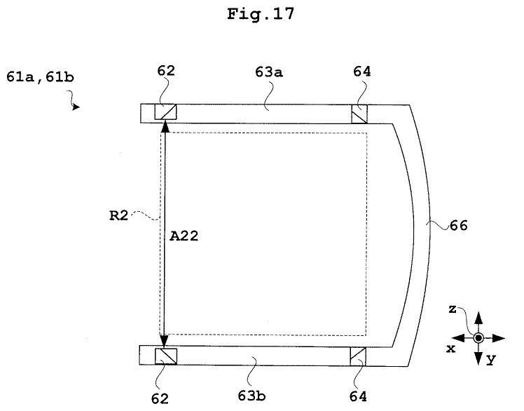

The second pickup hand 61a corresponds to a second hand according to the present invention. The second pickup hand 61a holds one unprocessed substrate W at a time from the carrier C, and transfers the substrate W onto the path 24. The first pickup hand 51a and the second pickup hand 61a have similar functions, but have different shapes (see FIGS. 16 and 17). The second pickup hand 61a includes a hand body 63 and a second guide member 62. The hand body 63 has a flat shape so as to be able to advance into the space between the substrates. The second guide member 62 is positioned at the tip end of the second pickup hand 61a, and is configured to abut against the end of the substrate W. The second guide member 62 is a tab provided at the tip end of the hand body 63, and is a member that comes into contact with the substrate W. The second guide member 62 is provided on the top surface of the hand body 63. The second guide member 62 has a thick portion and a thin portion, in the same manner as the first guide member 52 described above. The second guide member 62 thus has parts with different thicknesses in the height direction. A wall of the thick portion of the second guide member 62, the wall facing the base end of the second pickup hand 61a, can come into contact with the peripheral end (bevel portion) of the substrate W. A flat part facing upwards in the thin portion of the second guide member 62 can come into contact with the peripheral portion of the bottom surface of the substrate. A guide member is also provided at the base end of the hand body 63 (not illustrated in FIG. 14). The guide member form a contact portion that comes into contact with the substrate W in the second pickup hand 61a. The second pickup hand 61a is a hand for a low-speed transfer, and transfers one substrates W at a time, from the carrier C that stores therein a plurality of substrates W in the horizontal postures, with a predetermined interval therebetween in the vertical direction Z.

The second return hand 61b has the same configuration as the second pickup hand 61a described above. In other words, the second return hand 61b includes the hand body 63 and the second guide member 62. The second return hand 61b and the second pickup hand 61a share the same configuration in which the second guide members 62 are provided at the tip end and the base end of the hand body 63, respectively, and each of the second guide member 62 has a thick portion and a thin portion. The second return hand 61b according to this example is provided to transfer the cleaned substrate W. By using different hands in a path for moving forwards and a path for moving rearwards in the operation of moving the substrate W back and forth, it is not necessary to use a hand having held an uncleaned substrate W in holding a cleaned substrate W. By providing the second return hand 61b, the cleanliness of the cleaned substrate W can be maintained.

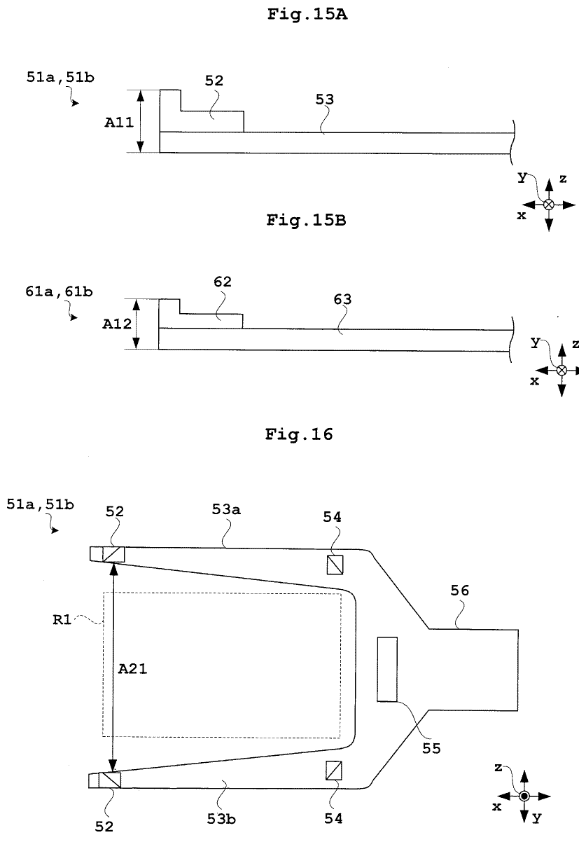

FIG. 15A illustrates the tip end of the first pickup hand 51a and the first return hand 51b, and FIG. 15B illustrates the tip end of the second pickup hand 61a and the second return hand 61b. The thickness A11 of the tip end of the first pickup hand 51a and the first return hand 51b in the vertical direction Z corresponds to a distance between the top end of the thick portion of the first guide member 52 and the bottom end of the hand body 53. In the same manner, the thickness A12 of the tip end of the second pickup hand 61a or the second return hand 61b in the vertical direction Z at corresponds to a distance between the top end of the thick portion of the second guide member 62 and the bottom end of the hand body 63. The thickness A12 of the tip end of the second pickup hand 61a and the second return hand 61b in the height direction is smaller than the thickness A11 of the tip end of the first pickup hand 51a and the first return hand 51b in the height direction. Therefore, the second pickup hand 61a and the second return hand 61b can advance into a gap smaller than that the first pickup hand 51a and the first return hand 51b. Such a configuration is advantageous when the substrate W to be transferred is warped, and the substrates are close to each other. By contrast, the first pickup hand 51a and the first return hand 51b are capable of transferring substrates at a higher speed, than that the second pickup hand 61a and the second return hand 61b are capable of. This point will be described later.

FIG. 16 is a plan view for explaining the first pickup hand 51a and the first return hand 51b. The first pickup hand 51a and the first return hand 51b have the same configurations as the pickup hand 11a and the return hand 11b according to Embodiment 1. In other words, each of the first pickup hand 51a and the first return hand 51b includes a base end 56, and a first holding body 53a and a second holding body 53b that are branched out from the base end 56. Each of the first pickup hand 51a and the first return hand 51b includes a first holding body 53a that holds one end of the substrate W and extends in the front-back direction X, and a second holding body 53b that holds the other end of the substrate W and extends in the front-back direction X. The first guide members 52 are provided at the tip ends of the first holding body 53a and the second holding body 53b, respectively.

Guide members 54 are provided at the base ends of the first holding body 53a and the second holding body 53b, respectively. In the same manner as the first guide members 52 described above, each of the guide members 54 includes a thick portion having a wall with which the end (bevel portion) of the substrate W can come into contact, and a thin portion having a flat portion with which the peripheral portion of the bottom of the substrate can come into contact. The thick portion of the guide member 54 has the same thickness as the thick portion of the first guide member 52. The thin portion of the guide member 54 has the same thickness as the thin portion of the first guide member 52. The walls of the first guide members 52 and the guide members 54 are provided at positions belonging to a virtual circle that is slightly larger than the substrate W. As a result, the substrate W can fit inside the area for receiving the substrate W, the area being delineated by the thin portions of the first guide members 52 and the guide members 54.

Each of the first pickup hand 51a and the first return hand 51b have a pusher 55. The pusher 55 is provided to the tip end of the base end 56, and can push the substrate W held by the first guide members 52 and the guide member 54 in the frontward direction. The pusher 55 is enabled to open by moving rearwards, and to close by moving in the frontward direction. In order for the first holding body 53a and the second holding body 53b to hold the substrate W, to begin with, the first guide members 52 and the guide members 54 are caused to hold the substrate W, with the pusher 55 opened. The pusher 55 is then closed, so as to nip the substrate W between the first guide members 52 and the pusher 55. The substrate W is gripped in the manner described above. By contrast, neither the second pickup hand 61a nor the second return hand 61b has a pusher. Therefore, the second guide member 62 and the guide member 64 of the second pickup hand 61a, which will be described later, have a clearance with respect to the substrate W to be held. The second pickup hand 61a transfers the substrate W with the clearance ensured. The same applies to the second return hand 61b.

FIG. 17 is a plan view for explaining the second pickup hand 61a and the second return hand 61b. Each of the second pickup hand 61a and the second return hand 61b includes a base end 66, and a first blade 63a and a second blade 63b that are branched out from the base end 66. Each of the second pickup hand 61a and the second return hand 61b includes the first blade 63a that holds one end of the substrate W and extends in the front-back direction X, and the second blade 63b that holds the other end of the substrate W and extends in the front-back direction X. The second guide member 62 is provided at the tip end of each of the first blade 63a and the second blade 63b.

Guide members 64 are provided at the base ends of the first blade 63a and the second blade 63b, respectively. In the same manner as the guide members 54 described above, each of the guide member 64 includes a thick portion having a wall with which the end (bevel portion) of the substrate W can come into contact, and a thin portion having a flat portion with which the peripheral portion of the bottom of the substrate can come into contact. The thick portion of the guide member 64 has the same thickness as the thick portion of the second guide member 62. The thin portion of the guide member 64 has the same thickness as the thin portion of the second guide member 62. The walls of the second guide members 62 and the guide members 64 are provided at positions belonging to a virtual circle that is slightly larger than the substrate W. As a result, the substrate W can fit inside the area for receiving the substrate W, the area being delineated by the thin portions of the second guide members 62 and the guide members 64.

The first pickup hand 51a and the second pickup hand 61a have shapes that are different from each other. In other words, as can be seen with reference to FIG. 16, each of the first holding body 53a and the second holding body 53b of the first pickup hand 51a has a tapered shape in which the thickness in the width direction Y increases from the tip end toward the base end. With such a configuration, the rigidity of the first pickup hand 51a is increased, and substrates can be transferred at a higher speed. The same kind of effect can also be achieved by the first return hand 51b.

By contrast, as can be seen with reference to FIG. 17, each of the first blade 63a and the second blade 63b included in the second pickup hand 61a have a constant thickness in the width direction Y, across the tip end toward the base end. With such a configuration, a wider space R2 can be ensured between the first blade 63a and the second blade 63b. Although the space R1 is ensured between the first holding body 53a and the second holding body 53b in the first pickup hand 51a illustrated in FIG. 16, the space R1 is smaller than the space R2, because the first holding body 53a and the second holding body 53b are tapered. The space between the first holding body 53a and the second holding body 53b is smaller than the space between the first blade 63a and the second blade 63b.

As can be seen with reference to FIG. 17, the second pickup hand 61a has the first blade 63a and the second blade 63b separated by the distance A22 that is greater than the distance A21 by which the first holding body 53a and the second holding body 53b of the first pickup hand 51a are separated (see FIGS. 17 and 16). In this manner, it is possible to ensure the space R2 that is wider than the space R1. With the wider space R2 ensured, the second pickup hand 61a can transfer a substrate W that is difficult to transfer, more reliably than the first pickup hand 51a. The substrate W that is difficult to transfer is, specifically, a warped substrate W. A warped substrate W is sometimes deformed in a shape recessed toward the center of the substrate W, and the warped substrate W is therefore more likely to come into contact with the hand, at the time of transfer. In this regard, the second pickup hand 61a has a configuration in which the first blade 63a and the second blade 63b are not provided to the parts where the warped substrate may come into contact. Therefore, the second pickup hand 61a according to this example can transfer the substrate W that is more difficult to transfer, reliably. The same kind of effect can also be achieved by the second return hand 61b.

A separation distance A21 is a distance between the first guide member 52 provided on the first holding body 53a and the first guide member 52 provided on the second holding body 53b. A separation distance A22 is a distance between the second guide member 62 provided on the first blade 63a and the second guide member 62 provided on the second blade 63b.

When the indexer robot IR transfers the substrate W in the carrier C onto the path 24, the indexer robot IR uses either the first pickup hand 51a or the second pickup hand 61a. The first pickup hand 51a or the second pickup hand 61a is advanced between the first substrate W1 that is the substrate to be transferred, and the second substrate W2 positioned below the first substrate W1 held in the carrier C, and is then raised to pick up the first substrate W1. The first substrate W1 thus picked up is transferred onto the path 24.

When the indexer robot IR transfers the substrate W on the path 24 into the carrier C, the indexer robot IR uses either the first return hand 51b or the second return hand 61b. The first return hand 51b or the second return hand 61b picks up the substrate W to be transferred held on the path 24, and is advanced into the carrier C. The first return hand 51b or the second return hand 61b is then lowered, to place the substrate W to be transferred on the carrier C. The first return hand 51b or the second return hand 61b is retracted by moving between the substrate W having been transferred and the substrate W positioned below the transferred substrate W, and is moved away from the carrier C.

### 12. Other Configurations

One example of the control related to the control unit 100 illustrated in FIG. 1 includes control related to the indexer robot IR. In other words, the control unit 100 controls the operation of advancing and retracting the first pickup hand 51a, the first return hand 51b, the second pickup hand 61a, and the second return hand 61b, the operation of opening and closing the pusher 55, the movement of the arm 13 in the vertical direction Z, a mapping sensor, to be described later, and an actuator mechanism for the mapping sensor. The control unit 100 also makes a selection as to which one of the four types of hands is to be used in the transfer. The storage unit has the same configurations as those according to Embodiment 1.

### 13. Sequence of Substrate Transfer

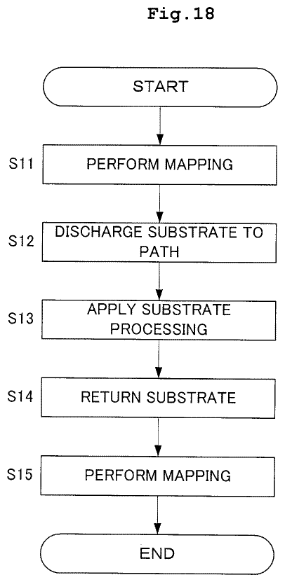

FIG. 18 is a flowchart of an operation for explaining the substrate transfer apparatus according to the present invention. An operation of the substrate transfer apparatus performed when the substrate processing apparatus 1 according to the present invention performs a substrate cleaning process will now be described. FIG. 13 illustrates how the substrate W is transferred inside the substrate processing apparatus 1. In the following description, FIG. 13 is also referred to, as appropriate.

Step S11: When the carrier C to be processed is placed at the load port 10, the substrate transfer apparatus starts the mapping operation of the substrate W. Because this step is the same as step S1 in Embodiment 1, detailed description thereof will be omitted.

With this step, it becomes possible to recognize how the comb-like member 7 of the carrier C holds the substrate W. The comb-like member 7 has twenty five protrusions, each of which is capable of holding a substrate W. For the convenience of description, it is assumed herein that substrates W that are fewer than twenty five are held in the carrier C. Among the substrates W held inside the carrier C, some substrates W are at the distance of 1 cm with respect to the substrate W below. 1 cm is the pitch at which the protrusions are provided to the comb-like member 7. Among the substrates W held inside the carrier C, other substrates W are at a distance of 2 cm with respect to the substrate W below. Therefore, the comb-like member 7 include: a vacant protrusion not having any substrate W; another protrusion holding one substrate W at a position of 1 cm above the vacant protrusion; and another protrusion holding another substrate W at a position of 1 cm below the vacant protrusion. Through the mapping operation, it is possible to recognize the part of the carrier C where the distance between the substrates is 1 cm, and another part of the carrier C where the distance between the substrates is 2 cm.

In the operation described with reference to FIG. 18, when the distance between the substrates is 2 cm and therefore has some extra room between the substrates for the hand to advance, the first pickup hand 51a and the first return hand 51b are used in the transfer. By contrast, when the distance between the substrates is 1 cm and there is no extra space for the hand to advance, the second pickup hand 61a and the second return hand 61b are used in transferring the substrate.

Step S12: The indexer robot IR is moved toward the back of the carrier C. The arm 13 of the indexer robot IR is then moved in the vertical direction. When the substrate W to be transferred is at the height of 2 cm with respect to substrate W below the substrate to be transferred, the first pickup hand 51a is positioned to the height of the substrate W to be transferred. The first pickup hand 51a is then caused to grip the substrate W to be transferred, and to discharge the substrate W onto the path 24 (see the arrow a in FIG. 13). At this time, the substrate W is transferred at a high speed. By contrast, when the substrate W to be transferred is at the height of 1 cm with respect to the substrate W below, the second pickup hand 61a is positioned to the height of the substrate W to be transferred. The second pickup hand 61a is then caused to hold the substrate W to be transferred, and to discharge the substrate W to the path 24. At this time, the substrate W is transferred at a lower speed.

Step S13: The unprocessed substrate W held on the path 24 is transferred to the single-wafer processing chamber 5a by the center robot CR (see an arrow b in FIG. 13). The single-wafer processing chamber 5a performs cleaning processing on the substrate W. The processed substrate W is then transferred to the path 24 by the center robot CR (see an arrow c in FIG. 13).

Step S14: The cleaned substrate W having been subjected to the cleaning processing is transferred either by the first return hand 51b or the second return hand 61b. The substrate W having been transferred to the path 24 using the first pickup hand 51a in step S12 is returned from the path 24 to the carrier C using the first return hand 51b. At this time, the substrate W is transferred at a high speed. The substrate W having been transferred to the path 24 using the second pickup hand 61a in step S12 is returned from the path 24 to the carrier C using the second return hand 61b (see the arrow d in FIG. 13). At this time, the substrate W is transferred at a lower speed. The substrate W having been resting on a certain protrusion in the comb-like member 7 of the carrier C is returned to the same protrusion through the substrate pick-up operation and the substrate return operation.

Step S15: Upon completing returning the substrate W to the carrier C, the substrate transfer apparatus repeats the mapping operation of the substrate W as in step S11. As a result, the operation of the substrate transfer apparatus according to this example is ended.

Note that the above description of the operations from step S1 to step S15 has focused on one substrate W. Therefore, in a case where a plurality of substrates W are to be transferred from the carrier C and the cleaning process of the substrates W is to be performed, step S12 may be repeated before the system control goes to step S13. In the same manner, step S14 may be repeated before the system goes to step S15.

Note that, when the position of an extensively warped substrate W in the carrier C is known in advance, the first pickup hand 51a and the second pickup hand 61a can be used selectively, according to an instruction from the user. In other words, for example, when all of the substrates W in the carrier C are warped, the arm 13 is controlled to use the second pickup hand 61a for all of the substrates W. By contrast, for example, when all the substrates W in the carrier C are flat, the arm 13 is controlled to use the first pickup hand 51a in the transfer of the substrates W. It is also possible to use the first pickup hand 51a and the second pickup hand 61a selectively for a single carrier C, by enabling the user to enter information about the shape of the substrate W at each position in the carrier C, into the substrate transfer apparatus. The shape of the substrate W herein is the degree by which the substrate W is warped.

### 14. Effects Achieved by Embodiment 2

The substrate transfer apparatus according to this example includes two types of hands, that is, the first pickup hand 51a and the first return hand 51b for the high-speed transfer, and the second pickup hand 61a and the second return hand 61b for the low-speed transfer, and also includes the control unit 100 that uses the first pickup hand 51a and the first return hand 51b, and the second pickup hand 61a and the second return hand 61b, selectively, to transfer the substrate W. With such a configuration, when the substrates W is closer to flat, it is possible to use the first pickup hand 51a and the first return hand 51b to transfer the substrates W at a high speed. When the substrates W are warped extensively, it is possible to use the second pickup hand 61a and the second return hand 61b to transfer the substrates W at a lower speed. In other words, with the substrate transfer apparatus according to the present invention, it is possible to transfer the substrates W using a method more suitable for the actual substrates W stored in the carrier C.

Furthermore, according to this example, the thickness A12 of the tip end of the second pickup hand 61a and the second return hand 61b in the height direction is smaller than the thickness A11 of the tip end of the first pickup hand 51a and the first return hand 51b in the height direction. With this configuration, by using the second pickup hand 61a and the second return hand 61b even when the substrate W is warped extensively and the minimum distance between the substrates is short, it is possible to transfer the substrate W to be transferred more reliably.

According to this example, the space R1 between the first holding body 53a and the second holding body 53b in the first pickup hand 51a and the first return hand 51b is smaller than the space R2 between the first blade 63a and the second blade 63b in the second pickup hand 61a or the second return hand 61b. With this configuration, the first pickup hand 51a and the first return hand 51b can hold the substrate W more reliably. Therefore, the substrate W can be transferred at a higher speed. By contrast, the second pickup hand 61a and the second return hand 61b can hold the substrate W having a warped shape, between the first blade 63a and the second blade 63b, reliably.

According to this example, each of the first pickup hand 51a and the first return hand 51b have the pusher 55 for gripping the substrate W. As a result, the first pickup hand 51a and the first return hand 51b can hold and transfer the substrate W reliably, and transfer the substrate W at a high speed. Neither the second pickup hand 61a nor the second return hand 61b has a pusher. With this configuration, it is possible to simplify the structure of the apparatus, and to reduce the thickness of the second pickup hand 61a and the second return hand 61b in the height direction.

### 15. Modifications of Present Invention

The present invention is not limited to the configurations described above, and following modifications are still possible.

### Modification 1

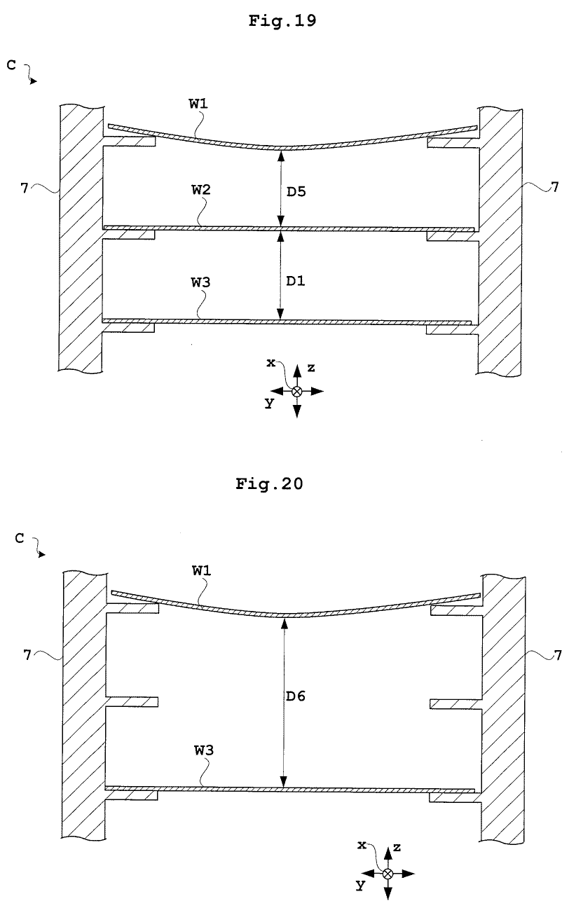

Explained in Embodiment 1 is a configuration in which the first substrate W1 determined to be untransferable is left out in the carrier C. However, present invention is not limited to this configuration, and it is also possible to transfer the first substrate W1. In the present modification, when the first substrate W1 is left out in the carrier C after the second substrate W2 is transferred from the carrier C, the first substrate W1 is transferred to the pickup hand 11a. FIG. 19 illustrates an arrangement in which the first substrate W1 warped downwards and the second substrate W2 below the first substrate W1 are placed on the comb-like member 7 of the carrier C. The third substrate W3 is located further below the second substrate W2 in the comb-like member 7. It is assumed herein that the actual measurement of the distance, having been measured by the sensor holding member 21, between the first substrate W1 and the second substrate W2 is D5. The distance D5 is too short for the pickup hand 11a and the return hand 11b to advance between the first substrate W1 and the second substrate W2. Therefore, it is not possible to transfer the first substrate W1 from the carrier C, as long as the second substrate W2 is present in the carrier C.

It is assumed herein that, by contrast, the actual measurement of the distance, having been measured by the sensor holding member 21, between the second substrate W2 and the third substrate W3 is D1. The distance D1 is long enough for the pickup hand 11a and the return hand 11b to advance between the second substrate W2 and the third substrate W3. Therefore, it is possible to transfer the second substrate W2 from the carrier C, regardless of whether the third substrate W3 is present.

FIG. 20 illustrates the carrier C after the second substrate W2 has been transferred from the carrier C. After the second substrate W2 has been transferred, there are the first substrate W1 and the third substrate W3 in the carrier C. Between the first substrate W1 and the third substrate W3, there is a vacant protrusion on the comb-like member 7. Therefore, the distance D6 between the first substrate W1 and the third substrate W3 is larger than at least the distance D1. In other words, the pickup hand 11a and the return hand 11b can advance into the space between the first substrate W1 and the third substrate W3. Therefore, even in the carrier C in the condition as illustrated in FIG. 19, by transferring the second substrate W2 and the first substrate W1, in the order listed herein, it is possible to transfer, from the carrier C, the first substrate W1 having been temporarily determined to be not transferrable. When these substrates W is to be returned to the carrier C, the first substrate W1 and the second substrate W2 may be transferred in the order listed herein.

In the configuration described above, when the first substrate W1 having been previously determined as not transferable is still in the carrier C after the second substrate W2 is transferred from the carrier C, the pickup hand 11a and the return hand 11b are caused to transfer the first substrate W1. With this configuration, it is possible to avoid the first substrate W1 from being left out in the carrier C until the end of the process.

### Modification 2

In Embodiment 1 described above, there has been no description as to a relationship between the speed of the sensor holding member 21 and the speeds of the pickup hand 11a and the return hand 11b to be advanced between the substrates. In this regard, the pickup hand 11a and the return hand 11b may be advanced at a speed higher than that at which the sensor holding member 21 is advanced. According to the present modification, the sensor holding member 21 is advanced between the first substrate W1 and the second substrate W2 at a first speed, and the pickup hand 11a is advanced between the first substrate W1 and the second substrate W2 at a speed higher than the first speed. In the configuration according to the present modification, because the pickup hand 11a and the return hand 11b are advanced between the substrates at a higher speed than that at which the sensor holding member 21 is advanced, an effect of speeding up the substrate transfer processing can be achieved. In addition, by setting the speed at which the sensor holding member 21 is advanced low, the sensor holding member 21 is prevented from coming into contact with the substrate W even when the sensor holding member 21 is advanced into a narrow space between the substrate, as described in FIG. 11B. By contrast, because the pickup hand 11a and the return hand 11b are not advanced between the substrates that are close to each other to the extent making the transfer impossible, to begin with, it is possible to increase the advancing speed.

### Modification 3

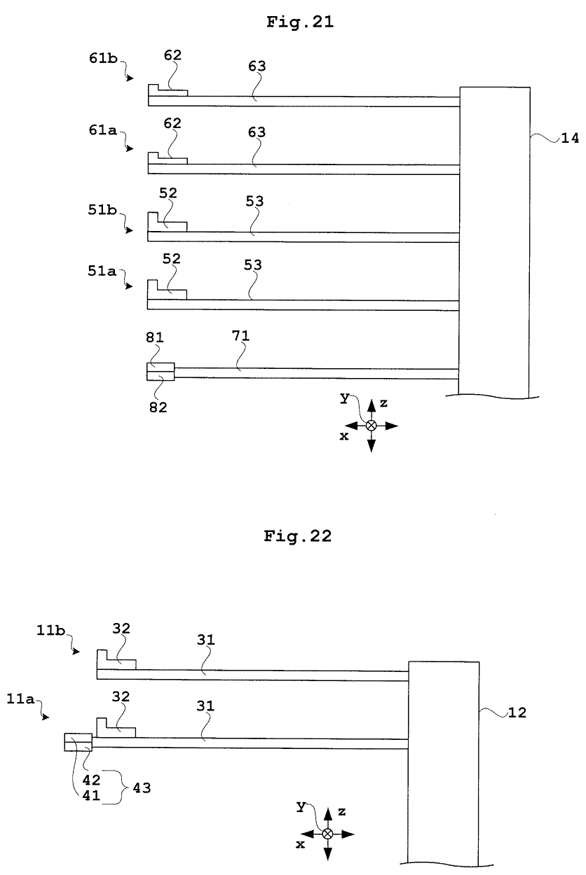

In Embodiment 2 described above, the sensor holding member 21 according to Embodiment 1 may be further provided. A sensor holding member 71 in FIG. 21 is a member that is advanced between the substrates W that are adjacent to each other. The sensor holding member 71 holds a first sensor 81 for measuring the distance to the substrate W above, and a second sensor 82 for measuring the distance to the substrate W below. By advancing the sensor holding member 71 between these substrates, actual measurements of the minimum distance between these substrates can be collected. Based on the actual measurement of the distance, it is possible to determine which hand is to be used in transferring the first substrate W1. In other words, when the first substrate W1 is warped extensively and it is better to carry the first substrate W1 at a lower speed, the second pickup hand 61a is used in the transfer of the first substrate W1. When the warpage of the first substrate W1 is limited and there would be no problem even if the substrate is transferred at high speed, the first pickup hand 51a is used in the transfer of the first substrate W1. When the first substrate W1 is warped extensively, the warpage makes the distance between the first substrate W1 and the second substrate W2 short. Therefore, it is better to transfer the substrate at a low speed. Furthermore, when the first substrate W1 is warped extensively, the first substrate W1 and the hand are more likely to come into contact. Therefore, the first substrate W1 is preferably transferred using the second pickup hand 61a having a wide space R2 between the first blade 63a and the second blade 63b. By contrast, when the first substrate W1 is flat, it is better to transfer the substrate at a high speed. In this manner, it is possible to improve the throughput of the substrate transfer apparatus.

### Modification 4

In Embodiment 1 described above, as illustrated in FIG. 22, the pickup hand 11a may also be used as the sensor holding member 21. In other words, the first sensor 41 and the second sensor 42 are attached to the pickup hand 11a. With this configuration, the sensor group 43 is provided at a position closer to the tip end of the hand body 31, than the position where the guide member 32 is provided. With this configuration, it is possible to provide a substrate transfer apparatus having a simple configuration without the sensor holding member 21.

What is claimed is:

1. A substrate transfer apparatus comprising:
a hand configured to hold and to transfer one substrate at a time, from a carrier that stores a plurality of substrates, in horizontal postures, with a predetermined interval between the substrates in a vertical direction, and that has an opening for taking out and storing substrate on one side surface, by advancing between adjacent upper and lower substrates;
a sensor holding member that is a member configured to be advanced between the adjacent upper and lower substrates, and that includes a first sensor configured to measure a distance with respect to upper one of the adjacent upper and lower substrates, and a second sensor configured to measure a distance with respect to a lower one of the adjacent upper and lower substrates; and
a control unit configured to control to advance and to retract the hand and the sensor holding member between the adjacent upper and lower substrates, through the opening of the carrier, wherein
the control unit is configured:
to advance the sensor holding member between a first substrate that is a substrate to be transferred and a second substrate that is on a lower side of the first substrate, and to measure a minimum distance between the substrates, based on a sum of a first minimum distance and a second minimum distance, the first minimum distance being a distance with respect to the substrate at a first measurement point where the first sensor is closest to the first substrate, and the second minimum distance being a distance with respect to the substrate at a second measurement point where the second sensor is closest to the second substrate, and
to adjust a height at which the hand is advanced, based on the minimum distance between the substrates so that a distance between the hand and the first substrate and a distance between the hand and the second substrate both become equal to or more than a predetermined distance, when the hand is advanced between the first substrate and the second substrate.

2. The substrate transfer apparatus according to claim 1, wherein
the hand has a tip end provided with a guide member against which an end of a substrate comes into abutment,
the first sensor and the second sensor are provided to a tip end of the sensor holding member, and
the tip end of the sensor holding member has a thickness, in a height direction, thinner than a thickness of the tip end of the hand in the height direction.

3. The substrate transfer apparatus according to claim 1, wherein
the first sensor measures a distance while being moved from an end of the first substrate, the end being positioned at the opening of the carrier, toward a back of the carrier,
the second sensor measures a distance while being moved from an end of the second substrate, the end being positioned at the opening of the carrier, toward the back of the carrier, and
the control unit is configured:
to adjust a height at which the hand is advanced in such a manner that a predetermined distance or more is ensured between the hand and the first substrate and between the hand and the second substrate, at the first measurement point where the first sensor is positioned closest to the first substrate and at the second measurement point at which the second sensor is positioned closest to the second substrate.

4. The substrate transfer apparatus according to claim 3, wherein the control unit is configured to adjust the height at which the hand is advanced in such a manner that a distance between the hand and the first substrate at the first measurement point becomes equal to a distance between the hand and the second substrate at the second measurement point.

5. The substrate transfer apparatus according to claim 1, wherein the sensor holding member is configured not to transfer the substrate.

6. The substrate transfer apparatus according to claim 3, wherein the control unit is configured not to advance the hand between the first substrate and the second substrate when a distance between the first substrate and the second substrate is too short to adjust the distance between the hand and the first substrate at the first measurement point and the distance between the hand and the second substrate at the second measurement point to equal to or more than the predetermined distance, simultaneously.

7. The substrate transfer apparatus according to claim 1, wherein
a top surface of the sensor holding member is positioned higher than a bottom end of the first sensor, and
a bottom surface of the sensor holding member is positioned lower than a top end of the second sensor.

8. The substrate transfer apparatus according to claim 1, wherein
the hand has a first holding body that holds one end of the substrate, and a second holding body that holds another end of the substrate,
the sensor holding member includes at least two sensor groups each including the first sensor and the second sensor,
the first sensor group measures a distance between the first substrate and the second substrate at a position where the first holding body is advanced, and
a second sensor group measures a distance between the first substrate and the second substrate at a position where the second holding body is advanced.

9. The substrate transfer apparatus according to claim 8, wherein the sensor holding member includes a first projection extending correspondingly to the first holding body, and a second projection extending correspondingly to the second holding body.

10. The substrate transfer apparatus according to claim 9, wherein the sensor holding member includes the sensor group at a tip end of the first projection, and includes the sensor group at a tip end of the second projection.

11. The substrate transfer apparatus according to claim 9, wherein
the sensor holding member
is provided with the first sensor and the second sensor at the same position of the first projection, and
is provided with the first sensor and the second sensor at the same position of the second projection.

12. The substrate transfer apparatus according to claim 1, wherein
the control unit does not advance the hand between the first substrate and the second substrate when the distance between the first substrate and the second substrate is too short to advance the sensor holding member between the first substrate and the second substrate.

13. The substrate transfer apparatus according to claim 1, wherein
when the first substrate is left out in the carrier, after the second substrate is transferred from the carrier, the control unit causes the hand to transfer the first substrate.

14. The substrate transfer apparatus according to claim 1, wherein
the control unit is configured:
to advance the sensor holding member between the first substrate and the second substrate at a first speed, and
to advance the hand between the first substrate and the second substrate at a second speed that is higher than the first speed.

15. The substrate transfer apparatus according to claim 1, wherein
the sensor holding member is at a same position as a position of the hand before being advanced between the substrates.

16. The substrate transfer apparatus according to claim 1, wherein the hand is also used as the sensor holding member, and the first sensor and the second sensor are mounted on the hand.

17. A substrate processing apparatus comprising:
the substrate transfer apparatus according to claim 1; and
a processing unit configured to perform predetermined processing on the substrate transferred by the substrate transfer apparatus.
